(19) United States
(12) Patent Application Publication
(10) Pub. No.: US 2025/0133784 A1
(43) Pub. Date: Apr. 24, 2025

(54) SEMICONDUCTOR STRUCTURE AND METHOD FOR FORMING THE SAME

(71) Applicant: Taiwan Semiconductor Manufacturing Company, Ltd., Hsinchu (TW)

(72) Inventor: Jhon-Jhy LIAW, Zhudong Township, Hsinchu County (TW)

(73) Assignee: Taiwan Semiconductor Manufacturing Company, Ltd., Hsinchu (TW)

(21) Appl. No.: 18/490,081

(22) Filed: Oct. 19, 2023

(51) Int. Cl. H01L 29/06; H01L 21/8238; H01L 27/092; H01L 29/423; H01L 29/66; H01L 29/775; H01L 29/786

(52) U.S. Cl. CPC H10D 62/116; H10D 30/014; H10D 30/031; H10D 30/43; H10D 30/6735; H10D 30/6757; H10D 64/018; H10D 84/017; H10D 84/038; H10D 84/859

(57) ABSTRACT

A semiconductor structure includes a substrate; first nanostructures suspended over and vertically arranged over the substrate; a first gate structure wrapped around each of the first nanostructures; and gate spacers formed on opposite sides of the first gate structure and over a topmost one of the first nanostructures. The semiconductor structure further includes first source/drain features attached to opposite sides of the first nanostructures; and a first bottom dielectric layer formed over the substrate and below the first nanostructures. The first bottom dielectric layer is vertically sandwiched between the substrate and the first gate structure.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs and, for these advancements to be realized, similar developments in IC processing and manufacturing are needed.

As integrated circuit (IC) technologies progress towards smaller technology nodes, multi-gate metal-oxide-semiconductor field effect transistor (multi-gate MOSFET, or multi-gate devices) have been introduced to improve gate control by increasing gate-channel coupling, reducing off-state current, and reducing short-channel effects (SCEs). A multi-gate device generally refers to a device having a gate structure, or portion thereof, disposed over more than one side of a channel region. Gate-all-around (GAA) transistors are examples of multi-gate devices that have become popular and promising candidates for high performance and low leakage applications. A GAA transistor has a gate structure that can extend, partially or fully, around a channel region to provide access to the channel region on two or more sides. While existing GAA transistors may be generally adequate for their intended purposes, they are not entirely satisfactory in all aspects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a fragmentary diagrammatic top view of an integrated circuit (IC) chip, in portion or entirety, in accordance with some embodiments of the present disclosure.

FIGS. 2A, 2B, 2C, 2D, and 2E are circuit schematics of various STD cells in the array of circuit cells in the logic region of the IC chip, in accordance with some embodiments of the present disclosure.

FIG. 3 is a perspective view of a GAA transistor in the array of circuit cells, in accordance with some embodiments of the present disclosure.

FIG. 4 illustrates a fragmentary diagrammatic top view (or layout) of a semiconductor structure in the logic region of the IC chip, in accordance with some embodiments of the present disclosure.

FIG. 5A illustrates a cross-sectional view of the semiconductor structure along a line A-A in FIG. 4, in accordance with some embodiments of the present disclosure.

FIG. 5B illustrates a cross-sectional view of the semiconductor structure along a line B-B in FIG. 4, in accordance with some embodiments of the present disclosure.

FIG. 5C illustrates a cross-sectional view of the semiconductor structure along a line C-C in FIG. 4, in accordance with some embodiments of the present disclosure.

FIG. 5D illustrates a cross-sectional view of the semiconductor structure along a line D-D in FIG. 4, in accordance with some embodiments of the present disclosure.

FIG. 5E illustrates a cross-sectional view of the semiconductor structure along a line E-E in FIG. 4, in accordance with some embodiments of the present disclosure.

FIG. 6A, 7A, 8A, 9A, 10A, 11, and 12 illustrate cross-sectional views of the semiconductor structure along a line A-A in FIG. 4, in accordance with some alternative embodiments of the present disclosure.

FIG. 6B, 7B, 8B, 9B, and 10B illustrate cross-sectional views of the semiconductor structure along a line B-B in FIG. 4, in accordance with some alternative embodiments of the present disclosure.

FIG. 7C illustrates a cross-sectional view of the semiconductor structure along a line D-D in FIG. 4, in accordance with some alternative embodiments of the present disclosure.

FIG. 13 is a Y-Z cross-sectional view of the semiconductor structure at various fabrication stages along a line C-C of FIG. 4, in accordance with some embodiments of the present disclosure.

FIGS. 14A, 15A, 16A, 17A, 18A, 19A, 20A, 21A, 22A, 23A, 24A, 25A, and 26A are X-Z cross-sectional views of the semiconductor structure at various fabrication stages along a line A-A of FIG. 4, in accordance with some embodiments of the present disclosure.

FIGS. 14B, 15B, 16B, 17B, 18B, 19B, 20B, 21B, 22B, 23B, 24B, 25B, and 26B are X-Z cross-sectional views of the semiconductor structure at various fabrication stages along a line B-B of FIG. 4, in accordance with some embodiments of the present disclosure.

FIGS. 14C, 15C, 16C, 17C, 18C, 19C, 20C, 21C, 22C, 23C, 24C, 25C, and 26C are Y-Z cross-sectional views of the semiconductor structure at various fabrication stages along a line C-C of FIG. 4, in accordance with some embodiments of the present disclosure.

FIGS. 27A and 28A are X-Z cross-sectional views of the semiconductor structure at various fabrication stages along a line A-A of FIG. 4, in accordance with some alternative embodiments of the present disclosure.

FIGS. 27B and 28B are X-Z cross-sectional views of the semiconductor structure at various fabrication stages along a line B-B of FIG. 4, in accordance with some alternative embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure is generally related to semiconductor structures, and more particularly to semiconductor structures with field-effect transistors (FETs), such as three-dimensional gate-all-around (GAA) transistors, in memory (e.g., SRAM) and/or standard logic cells of an integrated circuit (IC) structure. Generally, a GAA transistor may include a plurality of vertically stacked sheets (e.g., nanosheets), wires (e.g., nanowires), or rods (e.g., nanorods) in a channel region of the transistor, thereby allowing better gate control, lowered leakage current, and improved scaling capability for various IC applications.

The gate-all-around (GAA) transistor structures may be patterned by any suitable method. For example, the GAA transistor structures may be patterned using one or more photolithography processes, including double-patterning process or multi-patterning process. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA transistor.

Embodiments of the present disclosure offer advantages over the existing art, though it should be understood that other embodiments may offer different advantages, not all advantages are necessarily discussed herein, and no particular advantage is required for all embodiments. For example, embodiments discussed herein include a bottom dielectric layer formed below the gate structure and between the gate structure and underlying substrate. The bottom dielectric layer located below the gate structure can block the leakage path between source/drain regions, and thus the off-state drain-to-source leakage current Isoff can be reduced. Furthermore, the bottom dielectric layer sandwiched between the gate structure and the substrate can increase the distance between the metal gate structure and the well region in the substrate, and thus the capacitance between the gate structure and well region can be reduced. In addition, the structure with source/drain (S/D) features having undoped epitaxial layer located on opposite of the bottom dielectric layer can reduce the S/D junction leakage (off-state drain-to-bulk leakage current Iboff) and the S/D junction capacitance. Moreover, the provided structure with the bottom dielectric layer allows lowering anti-punch-through (APT) dosage or omitting the APT process. Therefore, the APT dosage out-diffusion impact can be eliminated, and thus the performance of threshold voltage (Vt) mismatch can be improved.

The various aspects of the present disclosure will now be described in more detail with reference to the figures. For avoidance of doubts, an X-direction, a Y-direction, and a Z-direction in the figures are perpendicular to one another and are used consistently. Throughout the present disclosure, like reference numerals denote like features unless otherwise excepted or described.

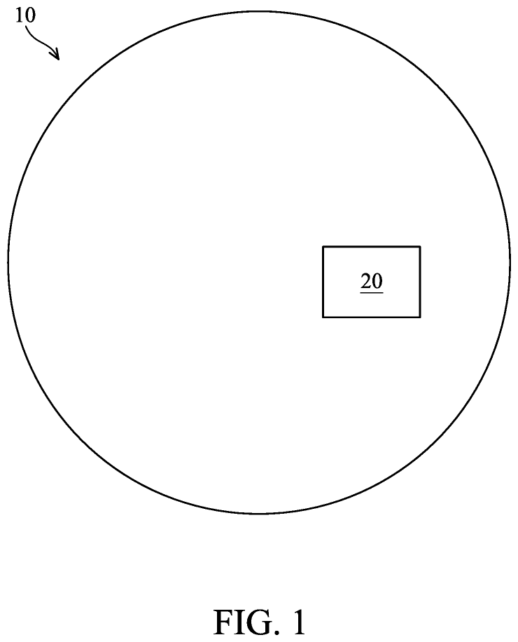

FIG. 1 is a fragmentary diagrammatic top view of an integrated circuit (IC) chip 10, in portion or entirety, in accordance with some embodiments of the present disclosure. The IC chip 10 may include various passive microelectronic devices and active microelectronic devices, such as resistors, capacitors, inductors, diodes, p-type field effect transistors (PFETs), n-type field effect transistors (NFETs), metal-oxide semiconductor field effect transistors (MOSFETs), complementary metal-oxide-semiconductor (CMOS) transistors, bipolar junction transistors (BJTs), laterally diffused MOS (LDMOS) transistors, high voltage transistors, high frequency transistors, other suitable components, or combinations thereof. The various microelectronic devices can be configured to provide the IC chip 10 with functionally distinct regions, such as a core region (also referred to as a logic region), a memory region (e.g., a static random access memory (SRAM) region), an analog region, a peripheral region (also referred to as an input/output (I/O) region), a dummy region, and/or other suitable regions.

As shown in FIG. 1, the IC chip 10 includes a logic region 20. The logic region 20 may include an array of circuit cells having various logic cells or standard (STD) cells. The logic cells or STD cells may include transistors and interconnect structures that combine to provide a logic device and/or a logic function, such as an inverter, an AND, an NAND, an OR, an NOR, a NOT, an XOR, an XNOR, other suitable logic devices, or combinations thereof. FIG. 1 has been simplified for the sake of clarity to better understand the inventive concepts of the present disclosure. Additional features can be added in the IC chip 10, and some of the features described herein can be replaced, modified, or eliminated in other embodiments of the IC chip 10.

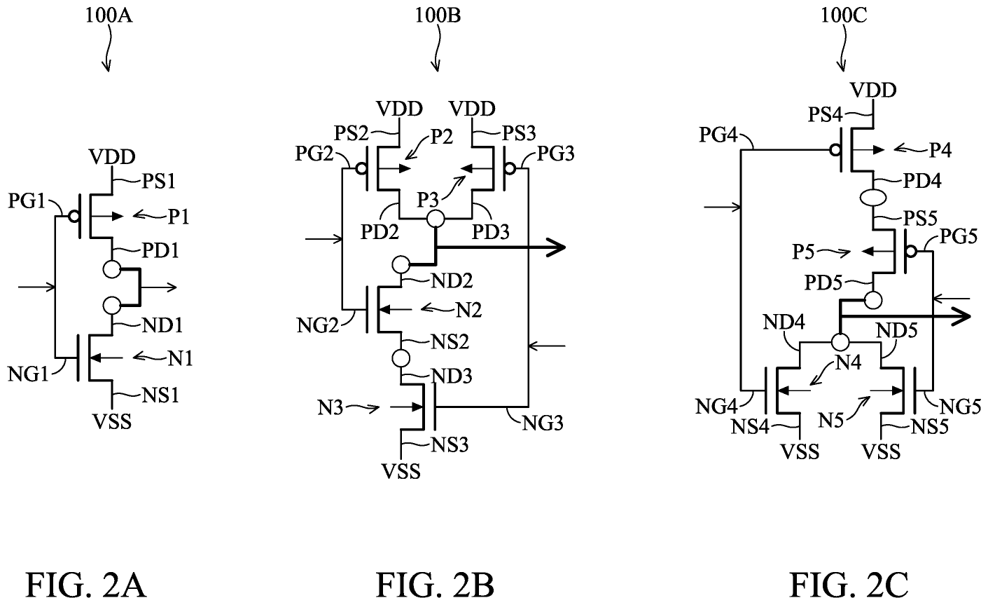

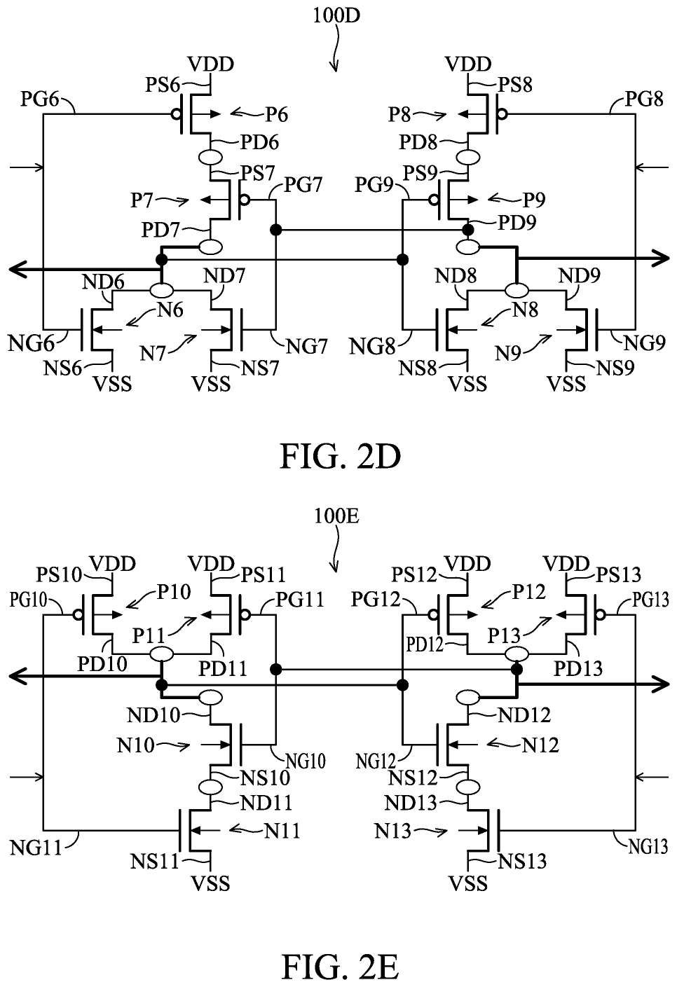

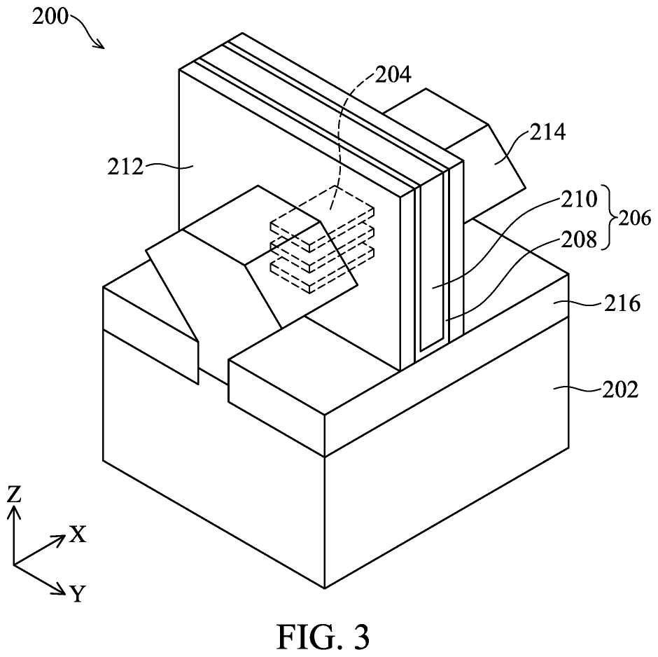

FIGS. 2A to 2E are circuit schematics of various STD cells in the array of circuit cells in the logic region 20 of the IC chip 10, in accordance with some embodiments of the present disclosure.

FIG. 2A illustrates an inverter 100A including an n-type transistor N1 and a P-type transistor P1. The n-type transistor N1 includes a source terminal NS1, a drain terminal ND1, and a gate terminal NG1. The P-type transistor P1 includes a source terminal PS1, a drain terminal PD1, and a gate terminal PG1.

As shown in FIG. 2A, the gate terminals NG1 and PG1 are coupled with each other to operate as an input terminal of the inverter 100A. The drain terminals ND1 and PD1 are coupled with each other to operate as an output terminal of the inverter 100A. The source terminal PS1 is coupled to a VDD voltage. The source terminal NS1 is coupled to a VSS voltage (or a ground voltage).

FIG. 2B illustrates a NAND (also referred to as a NAND logic gate, a NAND device or a NAND cell) 100B including n-type transistors N2, N3 and p-type transistors P2, P3. The n-type transistor N2 includes a source terminal NS2, a drain terminal ND2, and a gate terminal NG2, and the n-type transistor N3 includes a source terminal NS3, a drain terminal ND3, and a gate terminal NG3. The P-type transistor P2 includes a source terminal PS2, a drain terminal PD2, and a gate terminal PG2, and the P-type transistor P3 includes a source terminal PS3, a drain terminal PD3, and a gate terminal PG3.

As shown in FIG. 2B, the gate terminals NG2 and PG2 are coupled with each other to operate as a first input terminal of the NAND 100B. The gate terminals NG3 and PG3 are coupled with each other to operate as a second input terminal of the NAND 100B. The drain terminals ND2, PD2, and PD3 are coupled with each other to operate as an output terminal of the NAND 100B. In some embodiments, the connection of the drain terminals ND2, PD2, and PD3 are referred to as “common drain.” The source terminals PS2 and PS3 are coupled to the VDD voltage. The source terminal NS3 is coupled to VSS voltage. The source terminal NS2 and drain terminal ND3 are coupled with each other.

FIG. 2C illustrates a NOR (also referred to as a NOR logic gate, a NOR device or a NOR cell) 100C including n-type transistors N4, N5 and P-type transistors P4, P5. The n-type transistor N4 includes a source terminal NS4, a drain terminal ND4, and a gate terminal NG4, and the n-type transistor N5 includes a source terminal NS5, a drain terminal ND5, and a gate terminal NG5. The P-type transistor P4 includes a source terminal PS4, a drain terminal PD4, and a gate terminal PG4, and the P-type transistor P5 includes a source terminal PS5, a drain terminal PD5, and a gate terminal PG5.

As shown in FIG. 2C, the gate terminals NG4 and PG4 are coupled with each other to operate as a first input terminal of the NOR 100C, and the gate terminals NG5 and PG5 are coupled with each other to operate as a second input terminal of the NOR 100C. The drain terminals ND4, ND5, and PD5 are coupled with each other to operate as an output terminal of the NOR 100C. In some embodiments, the connection of the drain terminals ND4, ND5, and PD5 are referred to as “common drain.” The source terminal PS4 is coupled to the VDD voltage. The source terminals NS4 and NS5 are coupled to VSS voltage. The source terminal PS5 and drain terminal PD4 are coupled with each other.

FIG. 2D illustrates a flip-flop (also referred to as a flip-flop device or a flip-flop cell) 100D including n-type transistors N6, N7, N8, N9 and P-type transistors P6, P7, P8, P9. The n-type transistor N6 includes a source terminal NS6, a drain terminal ND6, and a gate terminal NG6, and the n-type transistor N7 includes a source terminal NS7, a drain terminal ND7, and a gate terminal NG7. The n-type transistor N8 includes a source terminal NS8, a drain terminal ND8, and a gate terminal NG8, and the n-type transistor N9 includes a source terminal NS9, a drain terminal ND9, and a gate terminal NG9. The P-type transistor P6 includes a source terminal PS6, a drain terminal PD6, and a gate terminal PG6, and the P-type transistor P7 includes a source terminal PS7, a drain terminal PD7, and a gate terminal PG7. The P-type transistor P8 includes a source terminal PS8, a drain terminal PD8, and a gate terminal PG8, and the P-type transistor P9 includes a source terminal PS9, a drain terminal PD9, and a gate terminal PG9.

As shown in FIG. 2D, the flip-flop 100D is a set-reset (SR) NOR latch. The NOR latch may include a pair of cross-coupled NOR. Specifically, the output terminal of a first NOR is coupled to the second input terminal of a second NOR, and the output terminal of the second NOR is coupled to the second input terminal of the first NOR. The details of the other connections of the flip-flop 100D are similar to the NOR 100C, and may not be described in detail herein.

FIG. 2E illustrates a flip-flop 100E including n-type transistors N10, N11, N12, N13 and P-type transistors P10, P11, P12, P13. The n-type transistor N10 includes a source terminal NS10, a drain terminal ND10, and a gate terminal NG10, and the n-type transistor N11 includes a source terminal NS11, a drain terminal ND11, and a gate terminal NG11. The n-type transistor N12 includes a source terminal NS12, a drain terminal ND12, and a gate terminal NG12, and the n-type transistor N13 includes a source terminal NS13, a drain terminal ND13, and a gate terminal NG13. The P-type transistor P10 includes a source terminal PS10, a drain terminal PD10, and a gate terminal PG1, and the P-type transistor P11 includes a source terminal PS11, a drain terminal PD11, and a gate terminal PG11. The P-type transistor P12 includes a source terminal PS12, a drain terminal PD12, and a gate terminal PG12, and the P-type transistor P13 includes a source terminal PS13, a drain terminal PD13, and a gate terminal PG13.

As shown in FIG. 2E, the flip-flop 100E is a SR NAND latch. The NAND latch may include a pair of cross-coupled NAND. Specifically, the output terminal of a first NAND is coupled to the first input terminal of a second NAND, and the output terminal of the second NAND is coupled to the first input terminal of the first NAND. The details of the other connections of the flip-flop 100E are similar to the NAND 100B, and may not be described in detail herein.

Each of the circuit cells discussed above is constructed by transistors. The transistors may be planar transistors, fin field-effect transistor (FinFET) transistors, gate-all-around (GAA) transistors, nano-wire transistors, nano-sheet transistors, or a combination thereof. For the sake of providing an example, an exemplary GAA transistor is illustrated in FIG. 3. However, it should be understood that the application should not be limited to a particular type of device, except as specifically claimed.

Referring to FIG. 3, a perspective view of an exemplary GAA transistor 200 is illustrated. The GAA transistor 200 is formed over a substrate 202. The substrate 202 may contains a semiconductor material, such as bulk silicon (Si). The GAA transistor 200 also includes one or more nanostructures 204 (dash lines) extending in the X-direction and vertically stacked (or arranged) in the Z-direction. More specifically, the nanostructures 204 are spaced apart from each other in the Z-direction. In some embodiments, the nanostructures 204 may also be referred to as channels, channel layers, nanosheets, or nanowires.

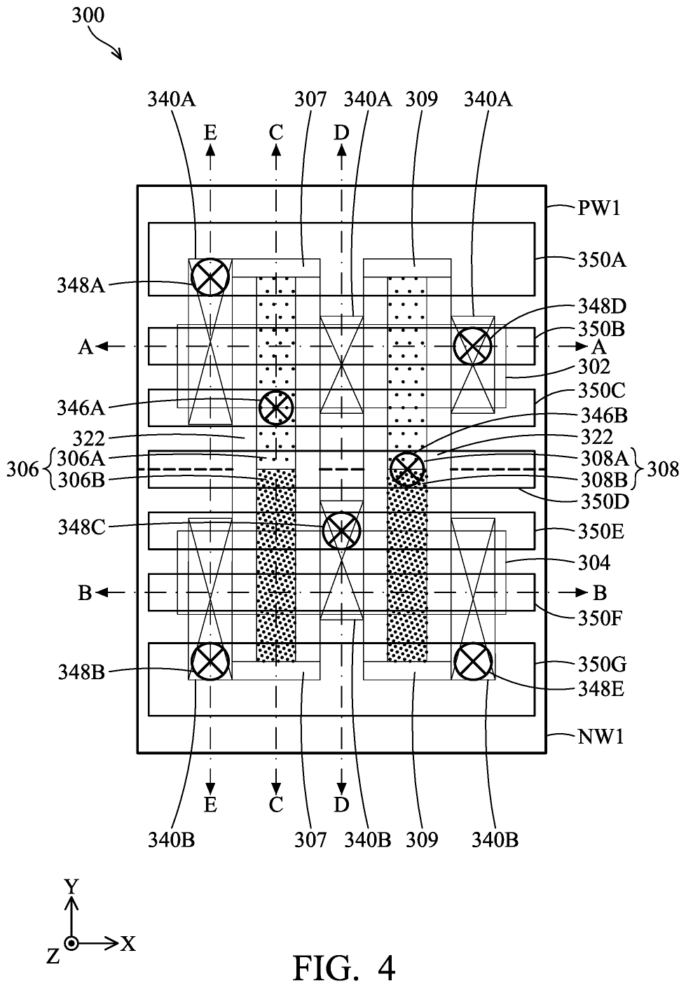

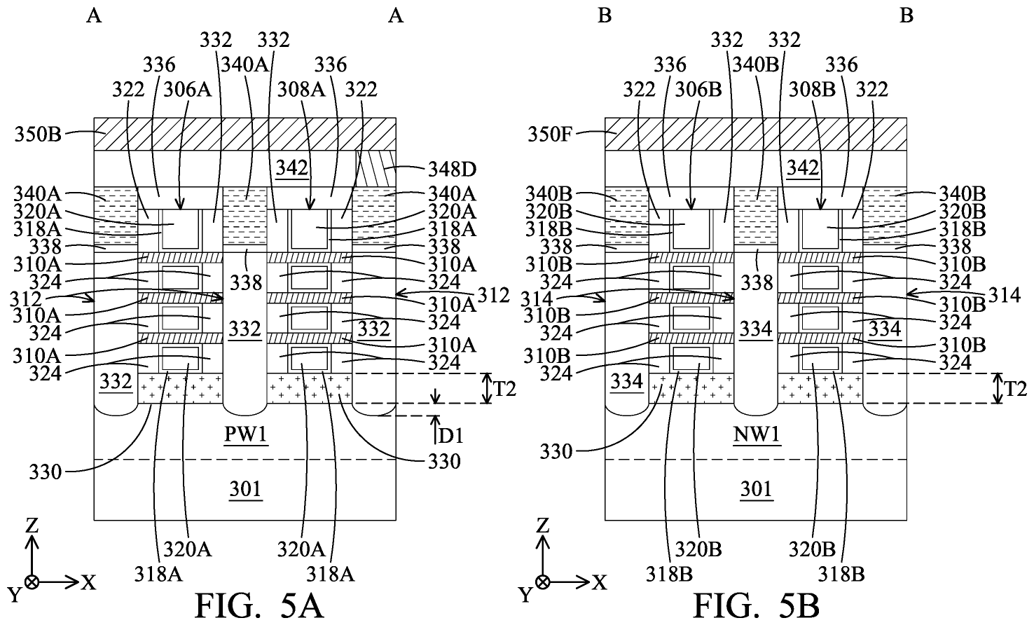

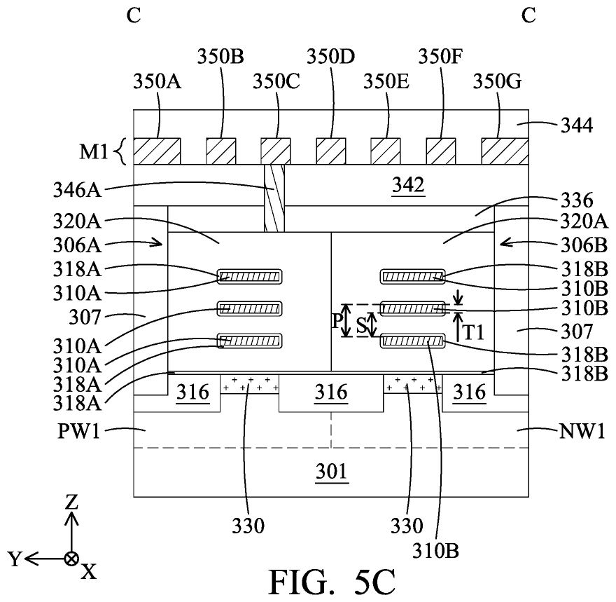

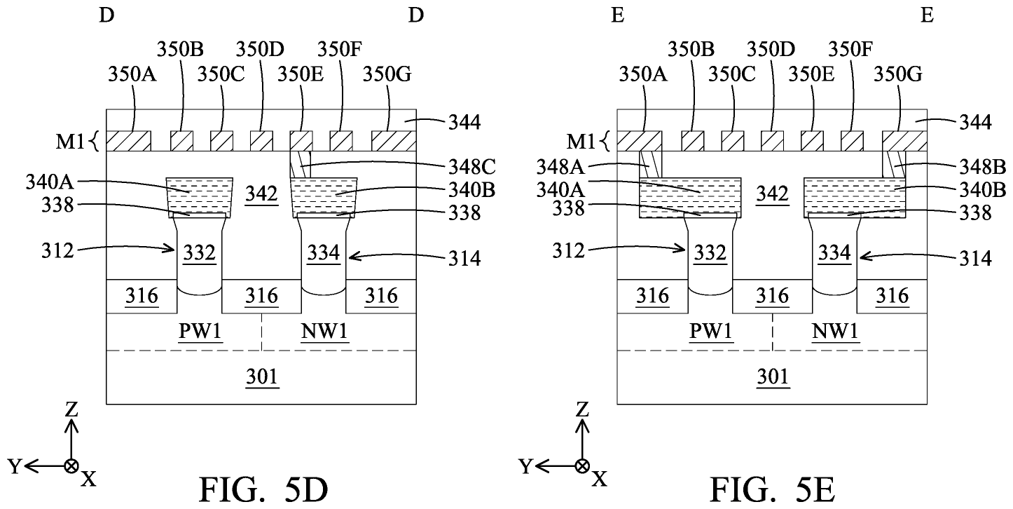

The GAA transistor 200 further includes a gate structure 206 including a gate dielectric layer 208 and a gate electrode 210. The gate dielectric layer 208 wraps around the nanostructures 204 and the gate electrode 210 wraps around the gate dielectric layer 208 (not shown in FIG. 3, may refer to FIGS. 5A to 5C). As shown in FIG. 3, gate spacers 212 are on sidewalls of the gate structure 206 and over the nanostructures 204 (not shown in FIG. 3, may refer to FIGS. 4, 5A, and 5B).

The GAA transistor 200 further includes source/drain features 214. As shown in FIG. 3, two source/drain features 214 are on opposite sides of the gate structure 206. The nanostructures 204 extends in the X-direction to connect one source/drain feature 214 to the other source/drain feature 214. The source/drain features 214 may also be referred to as source/drain, or source/drain regions. In some embodiments, source/drain feature(s) may refer to a source or a drain, individually or collectively dependent upon the context.

Isolation structure 216 is over the substrate 202 and under the gate dielectric layer 208, the gate electrode 210, and the gate spacers 212. The isolation structure 216 is used for isolating the GAA transistor 200 from other devices. In some embodiments, the isolation structure 216 may include different structures, such as shallow trench isolation (STI) structure, deep trench isolation (DTI) structure. Therefore, the isolation structure 216 is also referred as to as a STI feature or a DTI feature.

FIG. 4 illustrates a fragmentary diagrammatic top view (or layout) of a semiconductor structure 300 that may be disposed in the logic region 20 of the IC chip 10, in accordance with some embodiments of the present disclosure. FIG. 5A illustrates an X-Z cross-sectional view of the semiconductor structure 300 along a line A-A in FIG. 4, in accordance with some embodiments of the present disclosure. FIG. 5B illustrates an X-Z cross-sectional view of the semiconductor structure 300 along a line B-B in FIG. 4, in accordance with some embodiments of the present disclosure. FIG. 5C illustrates a Y-Z cross-sectional view of the semiconductor structure 300 along a line C-C in FIG. 4, in accordance with some embodiments of the present disclosure. FIG. 5D illustrates a Y-Z cross-sectional view of the semiconductor structure 300 along a line D-D in FIG. 4, in accordance with some embodiments of the present disclosure. FIG. 5E illustrates a Y-Z cross-sectional view of the semiconductor structure 300 along a line E-E in FIG. 4, in accordance with some embodiments of the present disclosure.

The semiconductor structure 300 may include CMOS devices, each of the CMOS devices includes an n-type MOSFET (NMOSFET) and a p-type MOSFET (PMOSFET). Each of the NMOSFET and the PMOSFET may be an embodiment of the GAA transistor 200. The semiconductor structure 300 may be used to constitute logic circuits or logic devices, such as inverters, NANDs, NORs, flip-flops, or the like. In the embodiment depicted in FIG. 4, the semiconductor structure 300 includes two CMOS devices that may constitute a NAND. It should be understood that the embodiment depicted in FIG. 4 is merely an example. The present disclosure can be applied to other logic circuits, such as NORs, ANDs, ORs, flip-flops, or the like.

Referring to FIGS. 4 and 5A-5E, the semiconductor structure 300 includes an active region 302 and an active region 304 that extend lengthwise in the X-direction, in accordance with some embodiments. Each of active regions 302 and 304 includes channel regions, source regions, and drain regions (where source regions and drain regions are collectively referred to as source/drain regions herein) of transistors (e.g., the GAA transistor 200) of the semiconductor structure 300. The active region 302 may be disposed over a p-type well region (or P-Well) PW1, and the active region 304 may be disposed over an n-type well region (or N-Well) NW1.

The semiconductor structure 300 may include a common gate structure 306 including gate structures 306A, 306B and a common gate structure 308 including gate structures 308A, 308B. The common gate structures 306 and 308 extend substantially parallel to one another, extend lengthwise in the Y-direction perpendicular to the X-direction, and are separated from each other in the X-direction. The gate structures 306A and 308A are over respective channel regions in the active region 302 and between respective source/drain regions in the active region 302. The gate structures 306B and 308B are over respective channel regions in the active region 304 and between respective source/drain regions in the active region 304.

In some embodiments, the gate structure 306A is engaged with the gate structure 306B, and the gate structure 308A is engaged with the gate structure 308B. In other embodiments, the gate structure 306A is separated from the gate structure 306B by an isolation structure, and/or the gate structure 308A is separated from the gate structure 308B by an isolation structure.

The active regions 302, 304 and the gate structures 306A, 306B, 308A, 308B are configured to provide transistors. In some embodiments, the gate structure 306A and the gate structure 308A engage the active region 302 (e.g., nanostructures 310A and source/drain features 312 that will be described in more detailed below) to construct a first NMOSFET and a second NMOSFET, respectively. In some embodiments, the gate structure 306B and the gate structure 308B engage the active region 304 (e.g., nanostructures 310B and source/drain features 314 that will be described in more detailed below) to construct a first PMOSFET and a second PMOSFET. In some embodiments, the first NMOSFET and the first PMOSFET constitute a first CMOS device, and the second NMOSFET and the second PMOSFET constitute a second CMOS device. In some embodiments, the first CMOS device and the second CMOS device are interconnected with each other to form a NAND device as NAND 100B described above.

The semiconductor structure 300 may include a substrate 301, over which the various features are formed, such as the common gate structures 306 and 308, nanostructures 310A and 310B, and source/drain features 312 and 314. In some embodiments, the substrate 301 is a p-type substrate. The substrate 301 may contains a semiconductor material, such as bulk silicon (Si). In other embodiments, the substrate 301 may include other semiconductors, such as germanium (Ge), silicon germanium (SiGe), or a III-V semiconductor material. Example III-V semiconductor materials may include gallium arsenide (GaAs), indium phosphide (InP), gallium phosphide (GaP), gallium nitride (GaN), gallium arsenide phosphide (GaAsP), aluminum indium arsenide (AlInAs), aluminum gallium arsenide (AlGaAs), gallium indium phosphide (GaInP), and indium gallium arsenide (InGaAs). Alternatively, the substrate 301 may be a semiconductor-on-insulator substrate, such as a silicon-on-insulator (SOI) substrate, a silicon germanium-on-insulator (SGOI) substrate, or a germanium-on-insulator (GOI) substrate. Semiconductor-on-insulator substrates may be fabricated using separation by implantation of oxygen (SIMOX), wafer bonding, and/or other suitable methods.

In some embodiments, the p-type well region PW1 and the n-type well region NW1 are formed in or on the substrate 301. In the embodiment depicted in FIGS. 4 and 5A-5E, the p-type well region PW1 is configured for n-type transistors, and the n-type well region NW1 is configured for p-type transistors. For example, the first NMOSFET constructed by the gate structure 306A and the active region 302 and the second NMOSFET constructed by the gate structure 308A and the active region 302 are formed on the p-type well region PW1. For example, the first PMOSFET constructed by the gate structure 306B and the active region 304 and the second PMOSFET constructed by the gate structure 308B and the active region 304 are formed on the n-type well region NW1. The p-type well region PW1 may be doped with p-type dopants, such as boron, indium, other p-type dopant, or a combination thereof. The n-type well region NW1 may be doped with n-type dopants, such as phosphorus, arsenic, other n-type dopant, or a combination thereof.

In some embodiments, the substrate 301 further includes other doped regions formed with a combination of p-type dopants and n-type dopants. The various n-type and p-type well regions can be formed directly on or in the substrate 301, for example, providing a p-well structure, an n-well structure, a dual-well structure, a raised structure, or combinations thereof. An ion implantation process, a diffusion process, and/or other suitable doping process may be performed to form the various wells.

Similar to the isolation structure 216 discussed above, the semiconductor structure 300 may further include isolation structures (or isolation features) 316. In some embodiments, the isolation structures 316 are over the substrate 301 and between the active regions 302 and 304. The isolation structures 316 also isolate the adjacent active regions (e.g., the active regions 302 and 304). The isolation structures 316 may include silicon oxide, silicon nitride, silicon oxynitride, other suitable isolation material (for example, including silicon, oxygen, nitrogen, carbon, or other suitable isolation constituent), or combinations thereof. The isolation structures 316 may include different structures, such as STI structures, DTI structures, and/or local oxidation of silicon (LOCOS) structures. In some embodiments, STI features include a multi-layer structure that fills the trenches, such as a silicon nitride comprising layer disposed over a thermal oxide comprising liner layer. In other embodiments, STI features include a dielectric layer disposed over a doped liner layer (including, for example, boron silicate glass (BSG) or phosphosilicate glass (PSG)). In certain embodiments, STI features include a bulk dielectric layer disposed over a liner dielectric layer, where the bulk dielectric layer and the liner dielectric layer include materials depending on design requirements.

Each transistor in the semiconductor structure 300 includes nanostructures similar to the nanostructures 204 discussed above. In some embodiments, the nanostructures 310A constituting vertical stacks are suspended and arranged vertically over the p-type well region PW1 and in the active region 302, as shown in FIG. 5A. In some embodiments, the nanostructures 310B constituting vertical stacks are suspended and arranged vertically over the n-type well region NW1 and in the active region 304, as shown in FIG. 5B. For the purpose of simplicity, the nanostructures 310A and 310B may be collectively referred to as nanostructures 310. In the depicted embodiments, three nanostructures 310 are vertically stacked (or vertically arranged) from each other in the Z-direction for one transistor. However, there may be another appropriate number of nanostructures in one transistor. For example, there may be from 2 to 10 nanostructures 310 in one transistor.

In some embodiments, the nanostructures 310 extend lengthwise in the X-direction (see FIGS. 5A and 5B) and widthwise in the Y-direction (see FIG. 5C). In some embodiments, each of the nanostructures 310 has a thickness T1 in the Z-direction, the thickness T1 is in a range from about 3 nm to about 10 nm, as shown in FIG. 5C. In some embodiments, nanostructures 310 are spaced apart from each other in the Z-direction by a spacing S in a range from about 3 nm to about 12 nm, as shown in FIG. 5C. In some embodiments, the nanostructures 310 has vertically a pitch P (P=T1+S) in the Z-direction, the pitch P is in a range from about 8 nm to about 20 nm.

The nanostructures 310 may include a semiconductor material, such as silicon, germanium, silicon carbide, silicon phosphide, gallium arsenide, gallium phosphide, indium phosphide, indium arsenide, and/or indium antimonide, silicon germanium (SiGe), SiPC, GaAsP, AlInAs, AlGaAs, GaInAs, GaInP, and/or GaInAsP. In some embodiments, the nanostructures 310A include silicon for n-type transistors. In some embodiments, the nanostructures 310B include silicon germanium for p-type transistors. In other embodiments, the nanostructures 310 are all made of silicon, and the type of the transistors depends on the work function metal layer that is wrapped around the nanostructures 310. In some embodiments, the nanostructures 310 are epitaxially grown using an epitaxial growth process such as vapor-phase epitaxy (VPE), metal-organic CVD (MOCVD), molecular beam epitaxy (MBE), although other deposition processes, such as chemical vapor deposition (CVD), low pressure CVD (LPCVD), plasma-enhanced CVD (PECVD), atomic layer deposition (ALD), ultrahigh vacuum CVD (UHVCVD), remote plasma CVD (RPCVD), a combination thereof, or the like, may also be utilized.

In some embodiments, the semiconductor structure 300 further includes gate end dielectrics 307 and gate end dielectrics 309. In some embodiments, the gate end dielectrics 307 and 309 are formed on the opposite sides of the common gate structure 306 and 308 in the Y direction, respectively, as shown in FIGS. 4 and 5C. In some embodiments, the gate end dielectrics 307 and 309 may include a dielectric material such as SiN, SiO₂, SiC, SiON, SiOC, SiCN, SiOCN, ZrSiO₂, HfO₂, HfSiO₄, LaO, Al₂O₃, combinations thereof, or the like, although any suitable material may be used. The methods of forming gate end dielectrics 307 and 309 may include forming a gate isolation trench through the gate structure, depositing a dielectric material in the gate isolation trench, and then performing an etching process such as an anisotropic etching process, although any suitable processes may be used.

In some embodiments, the gate structure 306A wraps around each of nanostructures 310A in corresponding vertical stack, the gate structure 308A wraps around each of nanostructures 310A in corresponding vertical stack, the gate structure 306B wraps around each of nanostructures 310B in corresponding vertical stack, and the gate structure 308B wraps around each of nanostructures 310B in corresponding vertical stack.

In some embodiments, the gate structures 306A and 308A each has a gate dielectric layer 318A and a gate electrode layer 320A, as shown in FIGS. 5A and 5C. The gate dielectric layers 318A wrap around each of the nanostructures 310A, and the gate electrode layers 320A wrap around the gate dielectric layers 318A. In some embodiments, the gate structures 306B and 308B each has a gate dielectric layer 318B and a gate electrode layer 320B, as shown in FIGS. 5B and 5C. The gate dielectric layers 318B wrap around each of the nanostructures 310B, and the gate electrode layers 320B wrap around the gate dielectric layers 318B. In some embodiments, each of the gate structures 306A, 306B, 308A, 308B further includes an interfacial layer (such as silicon dioxide, silicon oxynitride, or other suitable material layers) between the gate dielectric layer (e.g., gate dielectric layers 318A and 318B) and the nanostructures (e.g., nanostructures 310A and 310B).

In some embodiments, the gate dielectric layers 318A and 318B may include oxide with nitrogen doped dielectric material (initial layer) combined with metal content high-k dielectric material (k value (dielectric constant)>7.9). For example, the gate dielectric layers 318A and 318B may include hafnium oxide (HfO₂), which has a dielectric constant in a range from about 18 to about 40. Alternatively, the gate dielectric layers 318A and 318B may include other high-k dielectric materials, such as TiO₂, HfZrO, Ta₂O₃, HfSiO₄, ZrO₂, ZrSiO₂, LaO, AlO, ZrO, TiO, Ta₂O₅, Y₂O₃, SrTiO₃ (STO), BaTiO₃ (BTO), BaZrO, HfLaO, HfSiO, LaSiO, AlSiO, HfTaO, HfTiO, (Ba,Sr)TiO₃ (BST), Al₂O₃, Si₃N₄, oxynitrides (SiON), combinations thereof, or other suitable materials. The gate dielectric layers 318A and 318B may include the same or different material compositions. The gate dielectric layers 318A and 318B may be formed by chemical oxidation, thermal oxidation, CVD, physical vapor deposition (PVD), ALD, high-density plasma CVD (HDPCVD), MOCVD, RPCVD, PECVD, LPCVD, atomic layer CVD (ALCVD), atmospheric pressure CVD (APCVD), flowable CVD (FCVD), and/or other suitable methods. In some embodiments, each of the gate dielectric layers 318A and 318B has a thickness in a range from about 0.5 nm to about 3 nm.

In some embodiments, the gate electrode layers 320A are formed to wrap around the gate dielectric layers 318A and the center portions of the nanostructures 310A, as shown in FIGS. 5A and 5C. In some embodiments, the gate electrode layers 320B are formed to wrap around the gate dielectric layers 318B and the center portions of the nanostructures 310B, as shown in FIGS. 5B and 5C. In some embodiments, the gate electrode layers 320A may include one or more n-type work function metal layers for n-type transistors. In some embodiments, the n-type work function metal layer may include a material such as W, Cu, AlCu, TiAlC, TiAlN, TiAl, Pt, Ti, TiN, Ta, TaN, Co, Ni, Ag, Al, TaAl, TaAlC, TaC, TaCN, TaSiN, Mn, Zr, other suitable n-type work function materials, or combinations thereof. In some embodiments, the gate electrode layers 320B may include one or more p-type work function metal layers for p-type transistors. In some embodiments, the p-type work function metal layer may include a material such as such as W, Al, Cu, TiN, Ti, TiAlN, TiAl, Pt, Ta, TaN, Co, Ni, TaC, TaCN, TaSiN, TaSi₂, NiSi₂, Mn, Zr, ZrSi₂, Ru, AlCu, Mo, MoSi₂, WN, other suitable p-type work function materials, or combinations thereof. In other embodiments, the gate electrode layers 320A and the gate electrode layers 320B may include the same work function metal layer. The n-type work function metal layer and the p-type work function metal layer may be deposited utilizing CVD, PVD, ALD, HDPCVD, MOCVD, RPCVD, PECVD, LPCVD, ALCVD, APCVD, FCVD, or the like. However, any suitable materials and processes may be utilized to form the n-type work function metal layer and the p-type work function metal layer.

In some embodiments, each of the gate electrode layers 320A and 320B may include a single layer or alternatively a multi-layer structure. In some embodiments, each of the gate electrode layers 320A and 320B may further include a capping layer, a barrier layer, and a fill material (not shown). The capping layer may be formed adjacent to the gate dielectric layers 318A, 318B and may be formed from a metallic material such as TaN, Ti, TiAlN, TiAl, Pt, TaC, TaCN, TaSiN, Mn, Zr, TiN, Ru, Mo, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. The metallic material may be deposited using a deposition process such as CVD, PVD, ALD, HDPCVD, MOCVD, RPCVD, PECVD, LPCVD, ALCVD, APCVD, FCVD, or the like, although any suitable deposition process may be used.

The barrier layer may be formed adjacent the capping layer, and may be formed of a different material than the capping layer. For example, the barrier layer may be formed of one or more layers of a metallic material such as TiN, TaN, Ti, TiAlN, TiAl, Pt, TaC, TaCN, TaSiN, Mn, Zr, Ru, Mo, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. The barrier layer may be deposited using a deposition process such as CVD, PVD, ALD, HDPCVD, MOCVD, RPCVD, PECVD, LPCVD, ALCVD, APCVD, FCVD, or the like, although any suitable deposition process may be used. In some embodiments, the fill material may include a suitable conductive material, such as Al, W, and/or Cu. In some embodiments, the fill material may be deposited using a deposition process such as CVD, PVD, ALD, HDPCVD, MOCVD, RPCVD, PECVD, LPCVD, ALCVD, APCVD, FCVD, or the like, although any suitable deposition process may be used.

Similar to the gate spacers 212 discussed above, the semiconductor structure 300 may further include gate spacers 322 formed on sidewalls of the gate structures 306A, 306B, 308A, and 308B in the X-direction, and over the nanostructures 310 in the Z-direction, as shown in FIGS. 4, 5A, and 5B. Furthermore, the gate spacers 322 extend lengthwise in the Y-direction (e.g., parallel to the common gate structures 306 and 308), and are on opposite sides (or on opposite sidewalls) of the common gate structures 306 and 308 in the X-direction, as shown in FIG. 4. The gate spacers 322 are over the nanostructures 310 and on top sidewalls of the gate structures 306A, 306B, 308A, and 308B, and thus are also referred to as gate top spacers or top spacers. The gate spacers 322 may include one or more dielectric materials selected from a group consisting of silicon nitride (Si₃N₄), silicon oxide (SiO₂), silicon carbide (SiC), silicon oxycarbide (SiOC), silicon oxynitride (SiON), silicon oxycarbon nitride (SiOCN), carbon doped oxide, nitrogen doped oxide, porous oxide, air gap, or a combination thereof. In some embodiments, the gate spacers 322 may include a single layer or a multi-layer structure.

In some embodiments, the semiconductor structure 300 further includes inner spacers 324 on the sidewalls of the gate structures 306A, 306B, 308A, and 308B in the X-direction, and below the topmost nanostructures 310 and the gate spacers 322. Furthermore, the inner spacers 324 are laterally between source/drain features and gate structures, such as between the source/drain features 312 and the gate structures 306A and 308A, and between the source/drain features 314 and the gate structures 306B and 308B. The inner spacers 324 are also vertically between adjacent nanostructures 310 and between bottommost nanostructures 310 and the substrate 301 in the Z-direction.

In some embodiments, the inner spacers 324 may include one or more dielectric materials selected from a group consisting of silicon nitride (Si₃N₄), silicon oxide (SiO₂), silicon carbide (SiC), silicon oxycarbide (SiOC), silicon oxynitride (SiON), silicon oxycarbon nitride (SiOCN), air gap, or combinations thereof. In some embodiments, the inner spacers 324 include a dielectric material having higher k value (dielectric constant) than the gate spacers 322. In other embodiments, the inner spacers 324 include a dielectric material having lower k value than the gate spacers 322.

In some embodiments, the gate spacers 322 have a thickness in the X-direction that is in a range from about 3 nm to about 15 nm, and the inner spacers 324 have a thickness in the X-direction that is in a range from about 2 nm to about 12 nm. In some embodiments, the thickness of the gate spacers 322 in the X-direction and the thickness of the inner spacers 324 in the X-direction are the same. In other embodiments, the thickness of the gate spacers 322 in the X-direction is greater than the thickness of the inner spacers 324 in the X-direction, and the difference between the thicknesses of the gate spacer 322 and the inner spacers 324 is in a range from about 0.5 nm to about 5 nm.

In some embodiments, the semiconductor structure 300 further includes the source/drain features 312 over the substrate 301 and in the source/drain regions of the active region 302, as shown in FIGS. 5A, 5D, and 5E. More specifically, the source/drain features 312 are attached to opposite sides of the nanostructures 310A, and the gate structures 306A and 308A are respectively between two source/drain features 312 in the X-direction. In some embodiments, the semiconductor structure 300 further includes the source/drain features 314 over the substrate 301 and in the source/drain regions of the active region 304, as shown in FIGS. 5B, 5D, and 5E. More specifically, the source/drain features 314 are attached to opposite sides of the nanostructures 310B, and the gate structures 306B and 308B are respectively between two source/drain features 314.

In some embodiments, each of the source/drain features 312 includes a doped epitaxial layer 332 over the p-type well region PW1, as shown in FIGS. 5A, 5D, and 5E. In some embodiments, the doped epitaxial layer 332 may be formed by using epitaxial growth process such as VPE, MOCVD, MBE, although other deposition processes, such as CVD, LPCVD, PECVD, ALD, UHVCVD, RPCVD, a combination thereof, or the like, may also be utilized. In some embodiments, the doped epitaxial layer 332 may include epitaxially-grown material selected from a group consisting of SiP, SiC, SiPC, SiAs, Si, or a combination thereof. In some embodiments, the doped epitaxial layer 332 is an n-type doped epitaxial layer, and the epitaxially-grown material of the doped epitaxial layer 332 may be doped with n-type dopants (such as phosphorus, arsenic, other n-type dopant, or combinations thereof) and have a doping concentration in a range from about 2×10¹⁹/cm³ to 3×10²¹/cm³. In some embodiments, the doped epitaxial layer 332 extend into the p-type well region PW1, and is in direct contact with the p-type well region PW1. In some embodiments, the doped epitaxial layer 332 extend into the p-type well region PW1 in the Z-direction by a depth D1 that is in a range from about 5 nm to about 30 nm.

In some embodiments, each of the source/drain features 314 includes a doped epitaxial layer 334 over the n-type well region NW1, as shown in FIGS. 5B, 5D, and 5E. In some embodiments, the doped epitaxial layer 334 may be formed by using epitaxial growth process such as VPE, MOCVD, MBE, although other deposition processes, such as CVD, LPCVD, PECVD, ALD, UHVCVD, RPCVD, a combination thereof, or the like, may also be utilized. In some embodiments, the doped epitaxial layer 334 may include epitaxially-grown material selected from a group consisting of boron-doped SiGe, boron-doped SiGeC, boron-doped Ge, boron-doped Si, boron and carbon doped SiGe, or combinations thereof. In some embodiments, the doped epitaxial layer 334 is an p-type doped epitaxial layer, and the epitaxially-grown material of the doped epitaxial layer 334 may be doped with p-type dopants (such as boron, indium, other p-type dopant, or combinations thereof) and have a doping concentration in a range from about 1×10¹⁹/cm³ to 6×10²⁰/cm³. In some embodiments, the doped epitaxial layer 334 extend into the n-type well region NW1, and is in direct contact with the n-type well region NW1. In some embodiments, the doped epitaxial layer 334 extend into the n-type well region NW1 in the Z-direction by a depth that is in a range from about 5 nm to about 30 nm. In some embodiments, one or more annealing processes may be performed to activate the dopants in the doped epitaxial layers 332 and 334. The annealing processes may include rapid thermal annealing (RTA) and/or laser annealing processes.

In some embodiments, the semiconductor structure 300 further includes bottom dielectric layers 330 formed over the substrate 301 and below the nanostructures 310A and 310B, as shown in FIGS. 5A-5C. More specifically, the bottom dielectric layers 330 are over the substrate 301 (and over the p-type well region PW1 and the n-type well region NW1 formed in the substrate 301), below the nanostructures 310A and 310B, and below the gate structures 306A, 306B, 308A, and 308B in the Z-direction. In some embodiments, the bottom dielectric layers 330 are in contact with the gate structures 306A, 306B, 308A, and 308B. For example, the bottom dielectric layers 330 may be in contact with the gate dielectric layers 318A and 318B. In some embodiments, the bottom dielectric layers 330 are vertically sandwiched between the substrate 301 and the gate structures 306A, 306B, 308A, and 308B in the Z-direction. More specifically, the bottom dielectric layers 330 may be vertically sandwiched between the p-type well region PW1 and the gate structures 306A, 308A, and between the n-type well region NW1 and the gate structures 306B, 308B. In some embodiments, the bottom dielectric layers 330 separate the gate structures 306A, 306B, 308A, and 308B from the substrate 301 in the Z-direction. More specifically, the bottom dielectric layers 330 may separate the gate structures 306A and 308A from the p-type well region PW1, and separate the gate structures 306B and 308B from the n-type well region NW1.

In some embodiments, the bottom dielectric layers 330 are in contact with the inner spacers 324. For example, they may be in contact with the bottommost pairs of the inner spacers 324. In some embodiments, the bottom dielectric layers 330 are below the inner spacers 324 and are sandwiched between the bottommost pairs of the inner spacers 324 and the substrate 301 in the Z-direction. More specifically, the bottom dielectric layers 330 may be vertically sandwiched between the bottommost pairs of the inner spacers 324 and the p-type well region PW1/n-type well region NW1. In some embodiments, the bottom dielectric layers 330 separate the bottommost pairs of the inner spacers 324 from the substrate 301 in the Z-direction. More specifically, the bottom dielectric layers 330 may separate the bottommost pairs of the inner spacers 324 from the p-type well region PW1 and the n-type well region NW1. In some embodiments, the bottom dielectric layers 330 are in contact with the source/drain features 312 and 314 and are between the source/drain features 312 or the source/drain features 314 (e.g., the doped epitaxial layers 332 or 334) in the X-direction. In some embodiments, the doped epitaxial layers 332 contact opposite sides of the respective bottom dielectric layers 330 and the doped epitaxial layers 334 contact opposite sides of the respective bottom dielectric layers 330 in the X-direction.

In some embodiments, each of the bottom dielectric layers 330 has a thickness T2 in the Z-direction, the thickness T2 is in a range from about 3 nm to about 30 nm, as shown in FIGS. 5A and 5B. If the thickness T2 is too small, it is hard to deposit the material of the bottom dielectric layers 330 on the position where the bottom dielectric layers 330 to be formed. Moreover, if the thickness T2 is too small, the bottom dielectric layer 330 may not be able to carry out its functions, such as blocking the leakage path between source/drain regions to reduce Isoff and increasing the distance between the gate structure and the well region to reduce the capacitance therebetween. If the thickness T2 is too big, it is hard to completely fill the space where the bottom dielectric layers 330 to be formed, and/or the too much valuable space is occupied.

In some embodiments, the bottom dielectric layers 330 may include one or more dielectric materials selected from a group consisting of silicon nitride (Si₃N₄), silicon oxide (SiO₂), silicon carbide (SiC), silicon oxycarbide (SiOC), silicon oxynitride (SiON), silicon oxycarbon nitride (SiOCN), air gap, or combinations thereof. In some embodiments, the bottom dielectric layers 330 may include a single layer or a multi-layer structure. In some embodiments, the material of the bottom dielectric layers 330 is different than the material of the inner spacers. In other embodiments, the material of the bottom dielectric layers 330 is the same as the material of the inner spacers.

As described above, the bottom dielectric layer located below the gate structure can block the leakage path between source/drain regions. For example, the bottom dielectric layers 330 can block the leakage path below the gate structure 306A and between the source/drain features 312, the leakage path below the gate structure 308A and between the source/drain features 312, the leakage path below the gate structure 306B and between the source/drain features 314, and the leakage path below the gate structure 308B and between the source/drain features 314. Therefore, the off-state drain-to-source leakage current Isoff of the semiconductor structure 300 can be reduced. Furthermore, the bottom dielectric layers 330 increase the distance between the gate structure 306A and the p-type well region PW1, the distance between the gate structure 308A and the p-type well region PW1, the distance between the gate structure 306B and the n-type well region NW1, and the distance between the gate structure 308B and the n-type well region NW1. Therefore, the capacitance between the gate structures 306A/308A and the p-type well region PW1 and the capacitance between the gate structures 306B/308B and the n-type well region NW1 can be reduced.

Moreover, the existence of the bottom dielectric layers 330 can reduce the need for an APT process, and thus the APT dosage can be decreased or the APT process can be omitted. Therefore, the APT dosage out-diffusion impact can be eliminated, and the performance of the threshold voltage (Vt) mismatch can be improved. In addition, the enlargement of the gate spacers (e.g., the gate spacers 322 that are thicker than the inner spacers 324) can increase the distance between the gate structures (e.g., gate structures 306A, 306B, 3058A, and 308B) and the source/drain contacts (e.g., source/drain contacts 340A and 340B described in more detailed below), and thus the capacitance between the gate structures and the source/drain contacts can be reduced.

In some embodiments, the semiconductor structure 300 further includes gate top dielectrics 336 over the gate structures 306A, 306B, 308A, and 308B, as shown in FIGS. 5A-5C. In some embodiments, the gate top dielectrics 336 are also over the gate spacers 322. In some embodiments, the gate top dielectrics 336 may include dielectric materials, such as SiO₂, SiOC, SiON, SiOCN, carbon doped oxide, nitrogen doped oxide, carbon and nitrogen doped oxide, metal oxide dielectric, Hf oxide (HfO₂), Ta oxide (Ta₂O₅), Ti oxide (TiO₂), Zr oxide (ZrO₂), Al oxide (Al₂O₃), Y oxide (Y₂O₃), multiple metal content oxide, and a combination thereof. In some embodiments, the gate top dielectrics 336 may each include a single layer or a multi-layer structure. In some embodiments, the gate top dielectrics 336 has a thickness in the Z-direction that is in a range from about 2 nm to about 60 nm.

In some embodiments, the semiconductor structure 300 further includes source/drain contacts 340A and source/drain contacts 340B (may be collectively referred to as source/drain contacts 340) that extend in the Y-direction, as shown in FIGS. 4, 5A, 5B, 5D, and 5E. In some embodiments, the source/drain contacts 340A are over and electrically connected to the respective source/drain features 312. In some embodiments, two source/drain contacts 340A are on the opposite sides of the gate structure 306A, and two source/drain contacts 340A are on the opposite sides of the gate structure 308A. In some embodiments, the source/drain contacts 340B are over and electrically connected to the respective source/drain features 314. In some embodiments, two source/drain contacts 340B are on the opposite sides of the gate structure 306B, and two source/drain contacts 340B are on the opposite sides of the gate structure 308B.

Each of the source/drain contacts 340 may include a conductive material, such as Al, Cu, W, Co, Ru, Mo, Ti, Ta, Ru, Rh, Ir, Pt, TiN, TiAl, TiAlN, TaN, TaC, combinations thereof, or the like, and may be deposited using a deposition process such as sputtering, CVD, PVD, ALD, HDPCVD, MOCVD, RPCVD, PECVD, LPCVD, ALCVD, APCVD, FCVD, electroplating, electroless plating, or the like. However, any suitable materials and processes may be utilized to form source/drain contacts 340. In some embodiments, the source/drain contacts 340 may each include single conductive material layer or multiple conductive material layers.

In some embodiments, the top surfaces of the source/drain contacts 340 are substantially coplanar with the top surfaces of the gate top dielectrics 336. In the embodiments where the gate top dielectrics 336 are omitted, the top surfaces of the source/drain contacts 340 are substantially coplanar with the top surfaces of the gate structures (e.g., the gate structures 306A, 306B, 308A, and 308B). In other embodiments, the top surfaces of the source/drain contacts 340 are higher than the top surfaces of the gate top dielectrics 336.

In some embodiments, the semiconductor structure 300 further includes silicide layers 338, as shown in FIGS. 5A, 5B, 5D, and 5E. In some embodiments, the silicide layers 338 are between the source/drain features 312 and the source/drain contacts 340A, and between the source/drain features 314 and the source/drain contacts 340B. In some embodiments, the silicide layers 338 may include titanium silicide (TiSi), nickel silicide (NiSi), tungsten silicide (WSi), nickel-platinum silicide (NiPtSi), nickel-platinum-germanium silicide (NiPtGeSi), nickel-germanium silicide (NiGeSi), ytterbium silicide (YbSi), platinum silicide (PtSi), iridium silicide (IrSi), erbium silicide (ErSi), cobalt silicide (CoSi), or other suitable compounds.

In some embodiments, the semiconductor structure 300 further includes an inter-layer dielectric (ILD) layer 342 that is over the substrate 301, over the isolation structure 316, over the gate structures 306A/306B/308A/308B, between the source/drain features 312/314, and between the source/drain contacts 340A/340B, as shown in FIGS. 5A-5E. In some embodiments, the semiconductor structure 300 further includes an inter-metal dielectric (IMD) layer 344 over the ILD layer 342, the source/drain contacts 340, and the gate structures 306A/306B/308A/308B, as shown in FIGS. 5C-5E.

The ILD layer 342 and the IMD layer 344 may include a dielectric material including, for example, silicon oxide, silicon nitride, silicon oxynitride, TEOS-formed oxide, PSG, borophosphosilicate glass (BPSG), low-k dielectric material, other suitable dielectric material, or combinations thereof. Exemplary low-k dielectric materials include fluoride-doped silica glass (FSG), carbon doped silicon oxide, Black Diamond® (Applied Materials of Santa Clara, California), xerogel, aerogel, amorphous fluorinated carbon, parylene, BCB-based dielectric material, SiLK (Dow Chemical, Midland, Michigan), polyimide, other low-k dielectric material, or combinations thereof. In some embodiments, the ILD layer 342 and the IMD layer 344 are a dielectric layer that includes a low-k dielectric material (generally referred to as a low-k dielectric layer). The ILD layer 342 and the IMD layer 344 may include a multi-layer structure having multiple dielectric materials.

In some embodiments, the semiconductor structure 300 further includes gate vias 346A-346B, source/drain vias 348A-348E, and a metal layer M1, as shown in FIGS, 4 and 5A-5E. The gate vias 346A-346B and the source/drain vias 348A-348E are in the ILD layer 342, and the metal layer M1 is in the IMD layer 344. The materials of the gate vias 346A-346B, the source/drain vias 348A-348E, and the metal layer M1 are selected from a group consisting of titanium (Ti), titanium nitride (TiN), tantalum (Ta), tantalum nitride (TaN), titanium aluminum nitride (TiAlN), tungsten nitride (WN), tungsten (W), cobalt (Co), molybdenum (Mo), ruthenium (Ru), platinum (Pt), aluminum (Al), copper (Cu), other conductive materials, or combinations thereof.

In some embodiments, the metal layer M1 includes metal conductors 350A-350G that extend in the X-direction, and are over and electrically connected to the respective gate structures and the respective source/drain contacts, as shown in FIGS. 4 and 5A-5E. For example, the gate via 346A is on the common gate structure 306 and the metal conductor 350C is on the gate via 346A, such that the metal conductor 350C is electrically coupled to the common gate structure 306 through the gate via 346A. For example, the gate via 346B is on the common gate structure 308 and the metal conductor 350D is on the gate via 346B, such that the metal conductor 350D is electrically coupled to the common gate structure 308 through the gate via 346B.

For example, the source/drain via 348A is on first one of the source/drain contacts 340A and the metal conductor 350A is on the source/drain via 348A, such that the metal conductor 350A is electrically coupled to the first one of the source/drain contacts 340A through the source/drain via 348A. For example, the source/drain via 348B is on first one of the source/drain contacts 340B and the metal conductor 350G is on the source/drain via 348B, such that the metal conductor 350G is electrically coupled to the first one of the source/drain contacts 340B through the source/drain via 348B. For example, the source/drain via 348C is on second one of the source/drain contacts 340B and the metal conductor 350E is on the source/drain via 348C, such that the metal conductor 350E is electrically coupled to the second one of the source/drain contacts 340B through the source/drain via 348C. For example, the source/drain via 348D is on third one of the source/drain contacts 340A and the metal conductor 350B is on the source/drain via 348D, such that the metal conductor 350B is electrically coupled to the third one of the source/drain contacts 340A through the source/drain via 348D. For example, the source/drain via 348E is on third one of the source/drain contacts 340B and the metal conductor 350G is on the source/drain via 348E, such that the metal conductor 350G is electrically coupled to the third one of the source/drain contacts 340B through the source/drain via 348E.

As described above, in some embodiments, the semiconductor structure 300 includes a first CMOS device and a second CMOS device that collectively form a NAND device. In these embodiments, the metal conductor 350A may be a low voltage power line, such as a VSS power line, and the metal conductor 350G may be a high voltage power line, such as a VDD power line. In these embodiments, the first one of the source/drain contacts 340A (i.e., a source terminal of first NMOSFET) is couple to the metal conductor 350A (i.e., the VSS power line) through the source/drain via 348A. The first one of the source/drain contacts 340B (i.e., a source terminal of first PMOSFET) and the third one of the source/drain contacts 340B (i.e., a source terminal of second PMOSFET) are couple to the metal conductor 350G (i.e., the VDD power line) through the source/drain via 348B and the source/drain via 348E, respectively. In these embodiments, the first and second NMOSFETs share the second one of the source/drain features 312 and the second one of the source/drain contacts 340A (i.e., a drain terminal of first NMOSFET and a source terminal of second NMOSFET). The first and second PMOSFETs share the second one of the source/drain features 314 and the second one of the source/drain contacts 340B (i.e., drain terminals of first and second PMOSFET) that is coupled to the third one of the source/drain contacts 340A (i.e., a drain terminal of second NMOSFET). The second one of the source/drain contacts 340B is coupled to the third one of the source/drain contacts 340A through the source/drain vias 348C-348D, metal layer M1, and other metal layer overlying the metal layer M1 (not shown).

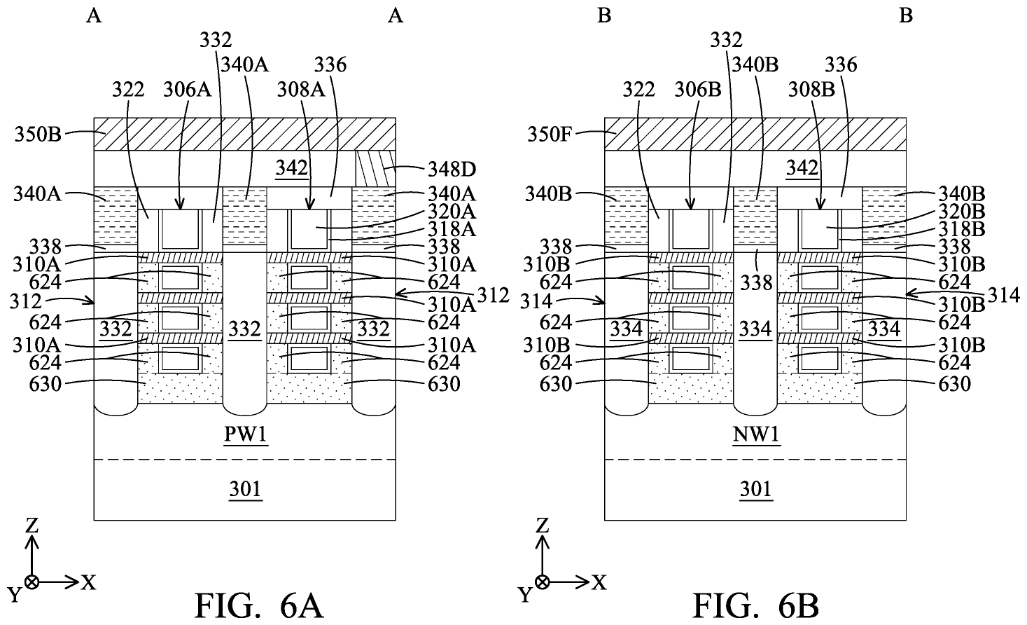

FIGS. 6A and 6B are cross-sectional views of the semiconductor structure 300 in FIG. 4 to illustrate alternative embodiments of the semiconductor structure 300. FIGS. 6A and 6B are taken along the lines A-A and B-B in FIG. 4, respectively. The structure shown in FIGS. 6A and 6B may be similar to the structure shown in FIGS. 5A and 5B described above, except the inner spacers 324 and the bottom dielectric layers 330 shown in FIGS. 5A and 5B are replaced by inner spacers 624 and bottom dielectric layers 630 shown in FIGS. 6A and 6B.

In some embodiments, the inner spacers 624 are on the sidewalls of the gate structures 306A, 306B, 308A, and 308B, and below the topmost nanostructures 310 and the gate spacers 322, as shown in FIGS. 6A and 6B. Furthermore, the inner spacers 624 are laterally between source/drain features and gate structures, such as between the source/drain features 312 and the gate structures 306A and 308A, and between the source/drain features 314 and the gate structures 306B and 308B. The inner spacers 324 are also vertically between adjacent nanostructures 310 and between bottommost nanostructures 310 and the substrate 301. In some embodiments, the materials and the dimensions of the inner spacers 624 are the same as or similar to that of the inner spacers 324, and are not repeated herein.

In some embodiments, the bottom dielectric layers 630 are over the substrate 301 and below the nanostructures 310A and 310B, as shown in FIGS. 6A and 6B. More specifically, the bottom dielectric layers 630 are over the substrate 301 (and over the p-type well region PW1 and the n-type well region NW1 formed in the substrate 301), below the nanostructures 310A and 310B, and below the gate structures 306A, 306B, 308A, and 308B in the Z-direction. In some embodiments, the bottom dielectric layers 630 are connected to the bottommost pairs of the inner spacers 624 (i.e., the inner spacers 624 that are between the bottommost nanostructures 310A/310B and the bottom dielectric layers 630). For example, each of the bottom dielectric layers 630 is connected to two inner spacers 624 below the bottommost nanostructures 310A or 310B. In some embodiments, the bottom dielectric layers 630 may be considered as portions of the inner spacers 624. In these embodiments, the bottom dielectric layers 630 and the inner spacers 624 are formed of the same material and formed in the same process. In these embodiments, the bottom dielectric layer 630 and the bottommost pair of the inner spacers 624 constitute a U-shaped isolation structure, and the U-shaped isolation structure separates the gate structure (e.g., the gate structures 306A, 306B, 308A, and 308B) from the substrate 301 (e.g., the p-type well region PW1 and the n-type well region NW1 formed in the substrate 301) in the Z-direction.

In some embodiments, the bottom dielectric layers 630 are in contact with the gate structures 306A, 306B, 308A, and 308B. For example, they may be in contact with the gate dielectric layers 318A and 318B. In some embodiments, the bottom dielectric layers 630 are vertically sandwiched between the substrate 301 (e.g., the p-type well region PW1 and the n-type well region NW1 formed in the substrate 301) and the gate structures 306A, 306B, 308A, and 308B in the Z-direction. In some embodiments, the bottom dielectric layers 630 separate the gate structures 306A, 306B, 308A, and 308B from the substrate 301 (e.g., the p-type well region PW1 and the n-type well region NW1 formed in the substrate 301) in the Z-direction. In some embodiments, the bottom dielectric layers 630 are sandwiched between the bottommost pairs of the inner spacers 624 and the substrate 301 (e.g., the p-type well region PW1 and the n-type well region

NW1 formed in the substrate 301) in the Z-direction. In some embodiments, the bottom dielectric layers 630 are in contact with the source/drain features 312 and 314, and are between the source/drain features 312 or the source/drain features 314 (e.g., the doped epitaxial layers 332 or 334) in the X-direction. In some embodiments, the doped epitaxial layers 332 contact opposite sides of the respective bottom dielectric layers 630 and the doped epitaxial layers 334 contact opposite sides of the respective bottom dielectric layers 630 in the X-direction. In some embodiments, the materials and the dimensions of the bottom dielectric layers 630 are the same as or similar to that of the bottom dielectric layers 330, and are not repeated herein.

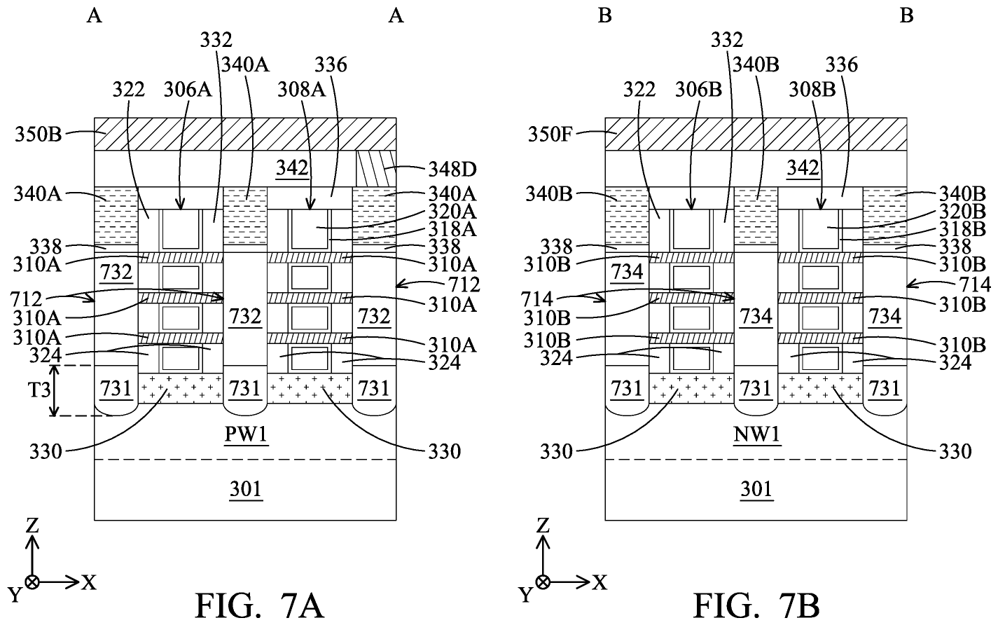

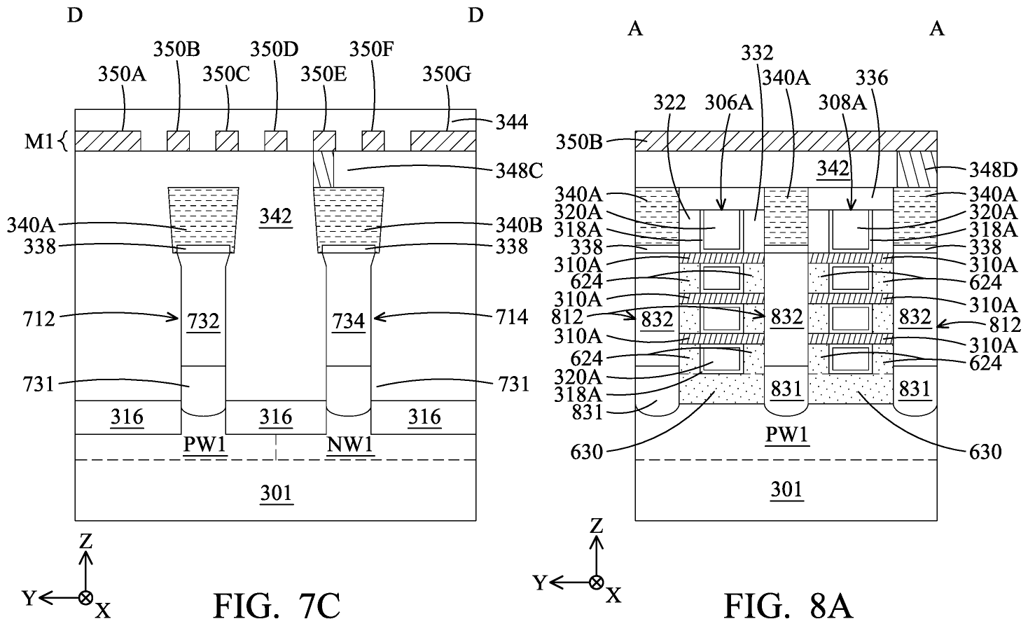

FIGS. 7A-7C are cross-sectional views of the semiconductor structure 300 in FIG. 4 to illustrate alternative embodiments of the semiconductor structure 300. FIGS. 7A, 7B, and 7C are taken along the lines A-A, B-B, and D-D in FIG. 4, respectively. The structure shown in FIGS. 7A-7C may be similar to the structure shown in FIGS. 5A, 5B, and 5D described above, except the source/drain features 312 and 314 shown in FIGS. 5A, 5B, and 5D are replaced by source/drain features 712 and 714 shown in FIGS. 7A-7C, respectively.

In some embodiments, each of the source/drain features 712 includes an undoped epitaxial layer 731 over the p-type well region PW1 and a doped epitaxial layer 732 over the undoped epitaxial layer 731, such that the undoped epitaxial layer 731 is between the doped epitaxial layer 732 and the p-type well region PW1, as shown in FIGS. 7A and 7C. In some embodiments, each of the source/drain features 714 includes an undoped epitaxial layer 731 over the n-type well region NW1 and a doped epitaxial layer 734 over the undoped epitaxial layer 731, such that the undoped epitaxial layer 731 is between the doped epitaxial layer 734 and the n-type well region NW1, as shown in FIGS. 7B and 7C. In some embodiments, the materials and methods used in forming the doped epitaxial layer 732 and 734 are the same as or similar to that of the doped epitaxial layer 332 and 334, respectively.

In some embodiments, the undoped epitaxial layers 731 are substantially free of dopants. The undoped epitaxial layers 731 may include silicon, germanium, silicon germanium, other suitable semiconductor materials, or combinations thereof. In some embodiments, the undoped epitaxial layers 731 include silicon that is substantially free of n-type dopants and p-type dopants. In some embodiments, the undoped epitaxial layers 731 are epitaxially grown using an epitaxial growth such as VPE, MOCVD, MBE, although other deposition processes, such as CVD, LPCVD, PECVD, ALD, UHVCVD, RPCVD, combinations thereof, or the like, may also be utilized.

In some embodiments, the undoped epitaxial layers 731 extend into the p-type well region PW1 or the n-type well region NW1 in the Z-direction by a depth that is in a range from about 5 nm to about 30 nm, and are in direct contact with the p-type well region PW1 or the n-type well region NW1. In some embodiments, each of the undoped epitaxial layers 731 has a thickness T3 in the Z-direction, the thickness T3 is in a range from about 5 nm to about 50 nm. In some embodiments, the top surface of the undoped epitaxial layer 731 is lower than the bottom surface of the bottommost nanostructure 310A/310B in the Z-direction. In some embodiments, the top surface of the undoped epitaxial layer 731 is higher than the top surface of the bottom dielectric layer 330 in the Z-direction. In other embodiments, the top surface of the undoped epitaxial layer 731 is lower than the top surface and higher than the bottom surface of the bottom dielectric layer 330 in the Z-direction. In certain embodiments, the top surface of the undoped epitaxial layer 731 is lower than the bottom surface of the bottom dielectric layer 330 in the Z-direction.

In some embodiments, the bottom dielectric layers 330 are in contact with the undoped epitaxial layers 731, and are between the undoped epitaxial layers 731 in the X-direction. In some embodiments, the undoped epitaxial layers 731 contact opposite sides of the respective bottom dielectric layers 330 in the X-direction. In some embodiments, the bottom dielectric layers 330 separate one undoped epitaxial layer 731 from another undoped epitaxial layer 731.

As described above, the structure with source/drain (S/D) features having undoped epitaxial layer located on opposite of the bottom dielectric layer can reduce the S/D junction leakage and the S/D junction capacitance. For example, the source/drain features 712 and 714 have the undoped epitaxial layers 731 formed on opposite sides the bottom dielectric layers 330. Therefore, the S/D junction leakage and the S/D junction capacitance can be reduced.

FIGS. 8A and 8B are cross-sectional views of the semiconductor structure 300 in FIG. 4 to illustrate alternative embodiments of the semiconductor structure 300. FIGS. 8A and 8B are taken along the lines A-A and B-B in FIG. 4, respectively. The structure shown in FIGS. 8A and 8B may be similar to the structure shown in FIGS. 6A and 6B described above, except the source/drain features 312 and 314 shown in FIGS. 6A and 6B are replaced by source/drain features 812 and 814 shown in FIGS. 8A and 8B, respectively.

In some embodiments, each of the source/drain features 812 includes an undoped epitaxial layer 831 over the p-type well region PW1 and a doped epitaxial layer 832 over the undoped epitaxial layer 831, such that the undoped epitaxial layer 831 is between the doped epitaxial layer 832 and the p-type well region PW1, as shown in FIG. 8A. In some embodiments, each of the source/drain features 814 includes an undoped epitaxial layer 831 over the n-type well region NW1 and a doped epitaxial layer 834 over the undoped epitaxial layer 831, such that the undoped epitaxial layer 831 is between the doped epitaxial layer 834 and the n-type well region NW1, as shown in FIG. 8B. In some embodiments, the materials, dimensions, and methods used in forming the undoped epitaxial layer 831, the doped epitaxial layer 832, and the doped epitaxial layer 834 are the same as or similar to that of the undoped epitaxial layer 731, the doped epitaxial layer 332, and the doped epitaxial layer 334, respectively.

In some embodiments, the undoped epitaxial layers 831 are in direct contact with the p-type well region PW1 or the n-type well region NW1. In some embodiments, the top surface of the undoped epitaxial layer 831 is lower than the bottom surface of the bottommost nanostructure 310A/310B in the Z-direction. In some embodiments, the top surface of the undoped epitaxial layer 831 is higher than the top surface of the bottom dielectric layer 630 in the Z-direction. In other embodiments, the top surface of the undoped epitaxial layer 831 is lower than the top surface and higher than the bottom surface of the bottom dielectric layer 630 in the Z-direction. In certain embodiments, the top surface of the undoped epitaxial layer 831 is lower than the bottom surface of the bottom dielectric layer 630 in the Z-direction.

In some embodiments, the bottom dielectric layers 630 are in contact with the undoped epitaxial layers 831, and are between the undoped epitaxial layers 831 in the X-direction. In some embodiments, the undoped epitaxial layers 831 contact opposite sides of the respective bottom dielectric layers 630 in the X-direction. In some embodiments, the bottom dielectric layers 630 separate one undoped epitaxial layer 831 from another undoped epitaxial layer 831.

FIGS. 9A and 9B are cross-sectional views of the semiconductor structure 300 in FIG. 4 to illustrate alternative embodiments of the semiconductor structure 300. FIGS. 9A and 9B are taken along the lines A-A and B-B in FIG. 4, respectively. The structure shown in FIGS. 9A and 9B may be similar to the structure shown in FIGS. 5A and 5B described above, except the inner spacers 324 and the bottom dielectric layers 330 shown in FIGS. 5A and 5B are replaced by inner spacers 924 and bottom dielectric layers 930 shown in FIGS. 9A and 9B, respectively.

In some embodiments, the bottom dielectric layers 930 are formed over the substrate 301 and below the nanostructures 310A and 310B, as shown in FIGS. 9A and 9B. More specifically, the bottom dielectric layers 930 are over the substrate 301 (e.g., over the p-type well region PW1 and the n-type well region NW1), below the nanostructures 310A and 310B, and below the gate structures 306A, 306B, 308A, and 308B in the Z-direction. In some embodiments, the bottom dielectric layers 930 are in contact with the gate structures 306A, 306B, 308A, and 308B. For example, they may be in contact with the gate dielectric layers 318A and 318B. In some embodiments, the bottom dielectric layers 930 are vertically sandwiched between the substrate 301 (e.g., the p-type well region PW1 and the n-type well region NW1 formed in the substrate 301) and the gate structures 306A, 306B, 308A, and 308B in the Z-direction. In some embodiments, the bottom dielectric layers 930 separate the gate structures 306A, 306B, 308A, and 308B from the substrate 301 (e.g., the p-type well region PW1 and the n-type well region NW1 formed in the substrate 301) in the Z-direction. In some embodiments, the thicknesses in the Z-direction and the materials of the bottom dielectric layers 930 are the same as or similar to that of the bottom dielectric layers 330.

In some embodiments, the inner spacers 924 include middle spacers 924A and bottom spacers 924B on the sidewalls of the gate structures 306A, 306B, 308A, and 308B, as shown in FIGS. 9A and 9B. Furthermore, the inner spacers 324 are laterally between source/drain features (e.g., the source/drain features 312 and 314) and gate structures (e.g., the gate structures 306A, 306B, 308A, and 308A). In some embodiments, the middle spacers 924A are vertically between adjacent nanostructures 310, and the bottom spacers 924B are vertically between the bottommost nanostructures 310 and the substrate 301, as shown in FIGS. 9A and 9B. That is, the pairs of the bottom spacers 924B are the bottommost pairs of the inner spacers 924. In some embodiments, the bottom spacers 924B extend downward and toward the substrate 301 in the Z-direction. In some embodiments, the height of the bottom spacer 924B is greater than the height of the middle spacers 924A in the Z-direction. In some embodiments, the dimensions in the X-direction and the materials of the inner spacers 924 are the same as or similar to that of the inner spacers 324.

In some embodiments, the bottom dielectric layers 930 are in contact with the inner spacers 924. For example, they may be in contact with the pairs of the bottom spacers 924B. In some embodiments, the bottom spacers 924B contact the opposite sides of the bottom dielectric layers 930 in the X-direction. In some embodiments, the bottom dielectric layers 930 are sandwiched between the pairs of the bottom spacers 924B in the X-direction. In some embodiments, the bottom spacers 924B are in contact with the source/drain features 312 or 314, and separate the bottom dielectric layers 930 from the source/drain features 312 or 314 in the X-direction. In some embodiments, the source/drain features 312 and/or 314 shown in FIGS. 9A and 9B may further include undoped epitaxial layers. For example, the source/drain features 312 and/or 314 may be replaced by the source/drain features 712 and/or 714 shown in FIG. 7A-7C. In these embodiments, the bottom spacers 924B may separate the bottom dielectric layers 930 from the undoped epitaxial layers in the X-direction.

FIGS. 10A and 10B are cross-sectional views of the semiconductor structure 300 in FIG. 4 to illustrate alternative embodiments of the semiconductor structure 300. FIGS. 10A and 10B are taken along the lines A-A and B-B in FIG. 4, respectively. The structure shown in FIGS. 10A and 10B may be similar to the structure shown in FIGS. 5A and 5B described above, except the source/drain features 312, the source/drain features 314, and the bottom dielectric layers 330 shown in FIGS. 5A and 5B are replaced by source/drain features 1012, the source/drain features 1014, and bottom dielectric layers 1030 shown in FIGS. 10A and 10B, respectively.

In some embodiments, each of the source/drain features 1012 includes a doped epitaxial layer 1032 over the p-type well region PW1, as shown in FIGS. 10A. In some embodiments, each of the source/drain features 1014 includes a doped epitaxial layer 1034 over the n-type well region NW1, as shown in FIGS. 10B. In some embodiments, the materials and methods used in forming the doped epitaxial layer 1032 and 1034 are the same as or similar to that of the doped epitaxial layer 332 and 334, respectively.

In some embodiments, the bottom dielectric layers 1030 are formed over the substrate 301 and below the nanostructures 310A and 310B, as shown in FIGS. 10A and 10B. More specifically, the bottom dielectric layers 1030 are over the substrate 301 (and over the p-type well region PW1 and the n-type well region NW1 formed in the substrate 301), below the nanostructures 310A and 310B, below the inner spacers 324, and below the gate structures 306A, 306B, 308A, and 308B in the Z-direction. In some embodiments, the bottom dielectric layers 1030 are in contact with the gate structures 306A, 306B, 308A, and 308B (e.g., in contact with the gate dielectric layers 318A and 318B) and the inner spacers 324 (e.g., in contact with the bottommost pairs of the inner spacers 324). In some embodiments, the bottom dielectric layers 1030 are vertically sandwiched between the substrate 301 and the gate structures 306A, 306B, 308A, and 308B, and vertically sandwiched between the substrate 301 and the bottommost pairs of the inner spacers 324 in the Z-direction. In some embodiments, the bottom dielectric layers 1030 separate the gate structures 306A, 306B, 308A, and 308B and the bottommost pairs of the inner spacers 324 from the substrate 301 in the Z-direction.

In some embodiments, the dimensions in the Z-direction and the materials of the bottom dielectric layers 1030 are the same as or similar to that of the bottom dielectric layers 330. In some embodiments, the bottom dielectric layers 1030 extend horizontally into the source/drain features 1012 or 1014 in the X-direction, as shown in FIGS. 10A and 10B. In some embodiments, the top surfaces and the bottom surfaces of the bottom dielectric layers 1030 are partially covered and the sidewalls of the bottom dielectric layers 1030 are covered by the source/drain features 1012 or 1014, such as covered by the doped epitaxial layers 1032 or 1034.

In some embodiments, the source/drain features 1012 and 1014 further include undoped epitaxial layers below the doped epitaxial layers (i.e., similar to the source/drain features 712 and 714 shown in FIGS. 7A and 7B). In these embodiments, the layers covering the bottom dielectric layers 1030 may be different due to the different configurations of the undoped and doped epitaxial layers. For example, when the top surfaces of the undoped epitaxial layers are higher than the top surfaces of the bottom dielectric layers 1030, the top surfaces and the bottom surfaces of the bottom dielectric layers 1030 are partially covered and the sidewalls of the bottom dielectric layers 1030 are covered by the undoped epitaxial layers. For example, when the top surfaces of the undoped epitaxial layers are lower than the top surfaces of the bottom dielectric layers 1030 but higher than the bottom surfaces of the bottom dielectric layers 1030, the top surfaces and the sidewalls of the bottom dielectric layers 1030 are partially covered by the doped epitaxial layers, and the bottom surfaces and the sidewalls of the bottom dielectric layers 1030 are partially covered by the undoped epitaxial layers. For example, when the top surfaces of the undoped epitaxial layers are lower than the bottom surfaces of the bottom dielectric layers 1030, the top surfaces and the bottom surfaces of the bottom dielectric layers 1030 are partially covered and the sidewalls of the bottom dielectric layers 1030 are covered by the doped epitaxial layers.

FIG. 11 is a cross-sectional view of the semiconductor structure 300 in FIG. 4 to illustrate alternative embodiments of the semiconductor structure 300. FIG. 11 is taken along the line A-A in FIG. 4. The structure shown in FIG. 11 is similar to the structure shown in FIG. 5A described above, except the source/drain features 312 and the bottom dielectric layers 330 shown in FIG. 5A are replaced by source/drain features 1112 and a bottom dielectric layer 1130 shown in FIG. 11. In these embodiments, the cross-sectional view of the semiconductor structure 300 taken along the line B-B in FIG. 4 is the same as FIG. 5B, 6B, 7B, 8B, 9B, or 10B.

In some embodiments, the source/drain features 1112 are over the substrate 301 and in the source/drain regions of the active region 302, as shown in FIG. 11. More specifically, the source/drain features 1112 are attached to opposite sides of the nanostructures 310A, and the gate structures 306A and 308A are respectively between two source/drain features 1112. In some embodiments, each of the source/drain features 1112 includes a doped epitaxial layer 1132 over the p-type well region PW1. In some embodiments, the materials and methods used in forming the doped epitaxial layer 1132 is the same as or similar to that of the doped epitaxial layer 332.

In some embodiments, the bottom dielectric layer 1130 is formed over the substrate 301 and below the nanostructures 310A, as shown in FIG. 11. More specifically, the bottom dielectric layer 1130 is over the p-type well region PW1 formed in the substrate 301, below the nanostructures 310A, below the inner spacers 324, below the source/drain features 1112, and below the gate structures 306A and 308A in the Z-direction. In some embodiments, the bottom dielectric layer 1130 is in contact with the gate structures 306A and 308A (e.g., in contact with the gate dielectric layers 318A), the bottommost pairs of the inner spacers 324 formed over the p-type well region PW1, and the source/drain features 1112.

In some embodiments, in the Z-direction, the bottom dielectric layer 1130 is vertically sandwiched between the substrate 301 and the gate structures 306A and 308A, vertically sandwiched between the substrate 301 and the bottommost pairs of the inner spacers 324 formed over the p-type well region PW1, and vertically sandwiched between the substrate 301 and the source/drain features 1112. In some embodiments, the bottom dielectric layer 1130 extends horizontally in the X-direction, and separate the gate structures 306A and 308A, the bottommost pairs of the inner spacers 324 formed over the p-type well region PW1, and the source/drain features 1112 from the substrate 301 in the Z-direction. In some embodiments, the dimensions in the Z-direction and the materials of the bottom dielectric layer 1130 are the same as or similar to that of the bottom dielectric layers 330.

FIG. 12 is a cross-sectional view of the semiconductor structure 300 in FIG. 4 to illustrate alternative embodiments of the semiconductor structure 300. FIG. 12 is taken along the line A-A in FIG. 4. The structure shown in FIG. 12 is similar to the structure shown in FIG. 6A described above, except the source/drain features 312, the inner spacers 624, and the bottom dielectric layers 630 shown in FIG. 6A are replaced by source/drain features 1212, inner spacers 1224, and a bottom dielectric layer 1230 shown in FIG. 12. In these embodiments, the cross-sectional view of the semiconductor structure 300 taken along the line B-B in FIG. 4 is the same as FIG. 5B, 6B, 7B, 8B, 9B, or 10B.

In some embodiments, the source/drain features 1212 are over the substrate 301 and in the source/drain regions of the active region 302, as shown in FIG. 12. More specifically, the source/drain features 1212 are attached to opposite sides of the nanostructures 310A, and the gate structures 306A and 308A are respectively between two source/drain features 1212. In some embodiments, each of the source/drain features 1212 includes a doped epitaxial layer 1232 over the p-type well region PW1. In some embodiments, the materials and methods used in forming the doped epitaxial layer 1232 is the same as or similar to that of the doped epitaxial layer 332.

In some embodiments, the inner spacers 1224 are on the sidewalls of the gate structures 306A and 308A, and below the topmost nanostructures 310A and the gate spacers 322 over the nanostructures 310A, as shown in FIG. 12. Furthermore, the inner spacers 1224 are laterally between source/drain features and gate structures, such as between the source/drain features 1212 and the gate structures 306A and 308A. The inner spacers 1224 are also vertically between adjacent nanostructures 310A and between bottommost nanostructures 310A and the substrate 301. In some embodiments, the materials and the dimensions of the inner spacers 1224 are the same as or similar to that of the inner spacers 324.

In some embodiments, the bottom dielectric layer 1230 are over the substrate 301 and below the nanostructures 310A, as shown in FIG. 12. More specifically, the bottom dielectric layer 1230 is over the p-type well region PW1 formed in the substrate 301, below the nanostructures 310A, below the source/drain features 1212, and below the gate structures 306A and 308A in the Z-direction. In some embodiments, the bottom dielectric layer 1230 is connected to the bottommost pairs of the inner spacers 1224 (i.e., the inner spacers 1224 that are between the bottommost nanostructures 310A and the bottom dielectric layer 1230). For example, the bottom dielectric layer 1230 is connected to the inner spacers 1224 that are below the bottommost nanostructures 310A. In some embodiments, the bottom dielectric layer 1230 may be considered as a portion of the inner spacers 1224. In these embodiments, the bottom dielectric layer 1230 and the inner spacers 1224 are formed of the same material and formed in the same process. In these embodiments, the bottom dielectric layer 1230 and the bottommost pairs of the inner spacers 1224 constitute U-shaped isolation structures, and the U-shaped isolation structures respectively separate the gate structure 306A and 308A from the p-type well region PW1 formed in the substrate 301 in the Z-direction.

In some embodiments, the bottom dielectric layer 1230 is in contact with the gate structures 306A and 308A (e.g., in contact with the gate dielectric layers 318A), the bottommost pairs of the inner spacers 1224, and the source/drain features 1212. In some embodiments, in the Z-direction, the bottom dielectric layer 1230 is vertically sandwiched between the substrate 301 and the gate structures 306A and 308A, vertically sandwiched between the substrate 301 and the bottommost pairs of the inner spacers 1224, and vertically sandwiched between the substrate 301 and the source/drain features 1212. In some embodiments, the bottom dielectric layer 1230 extends horizontally in the X-direction, and separates the gate structures 306A and 308A, the bottommost pairs of the inner spacers 1224, and the source/drain features 1212 from the substrate 301 in the Z-direction. In some embodiments, the dimensions in the Z-direction and the materials of the bottom dielectric layer 1230 are the same as or similar to that of the bottom dielectric layers 330.

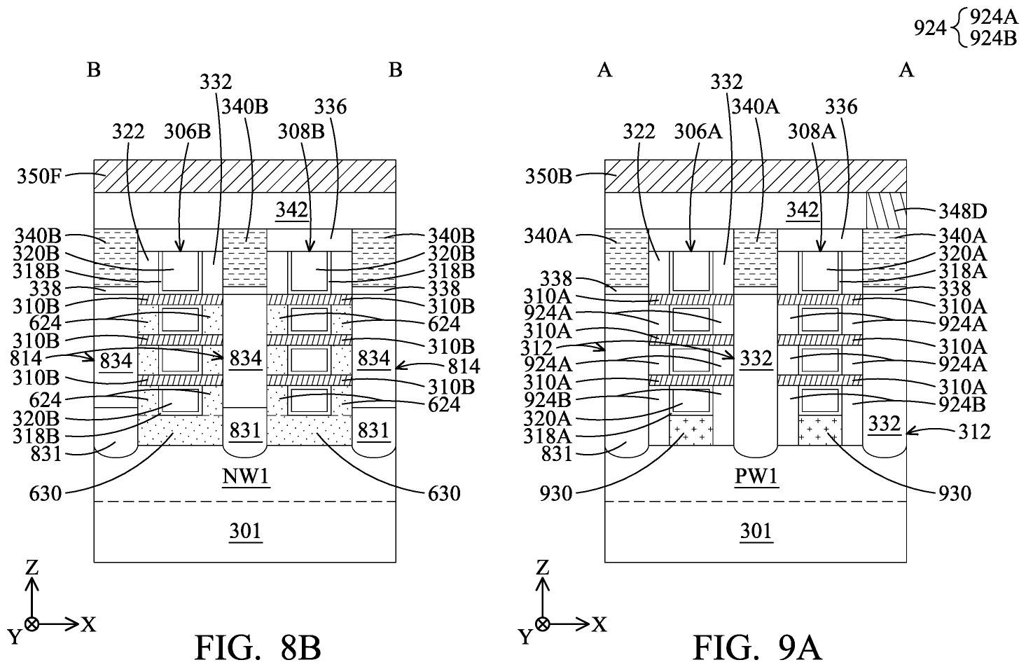

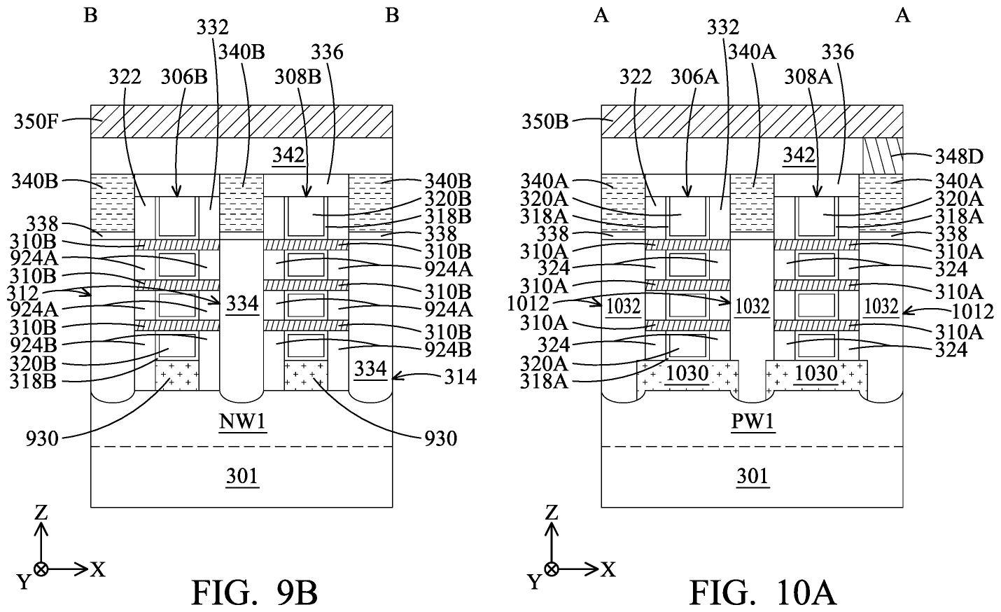

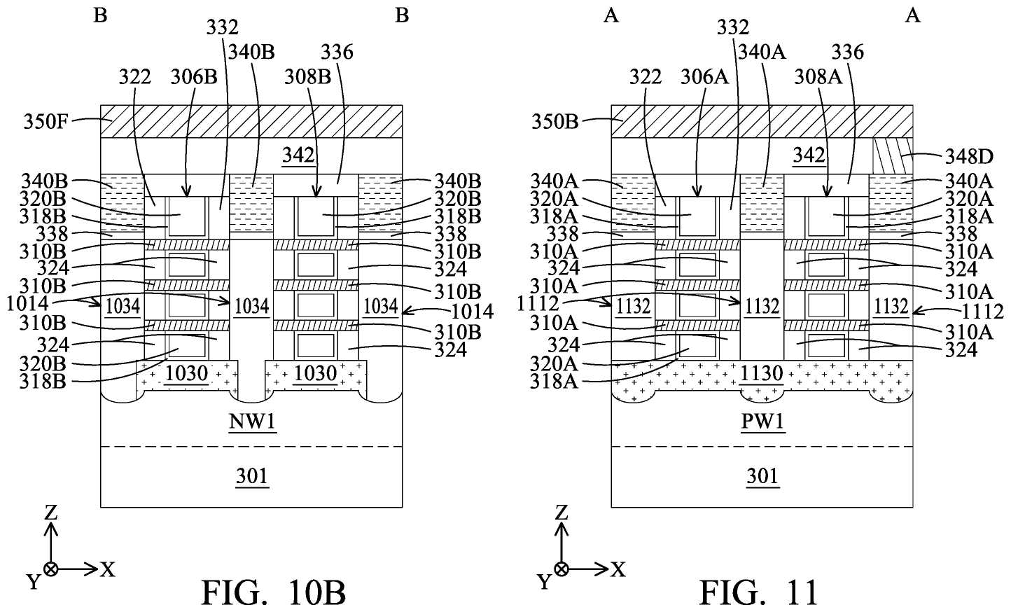

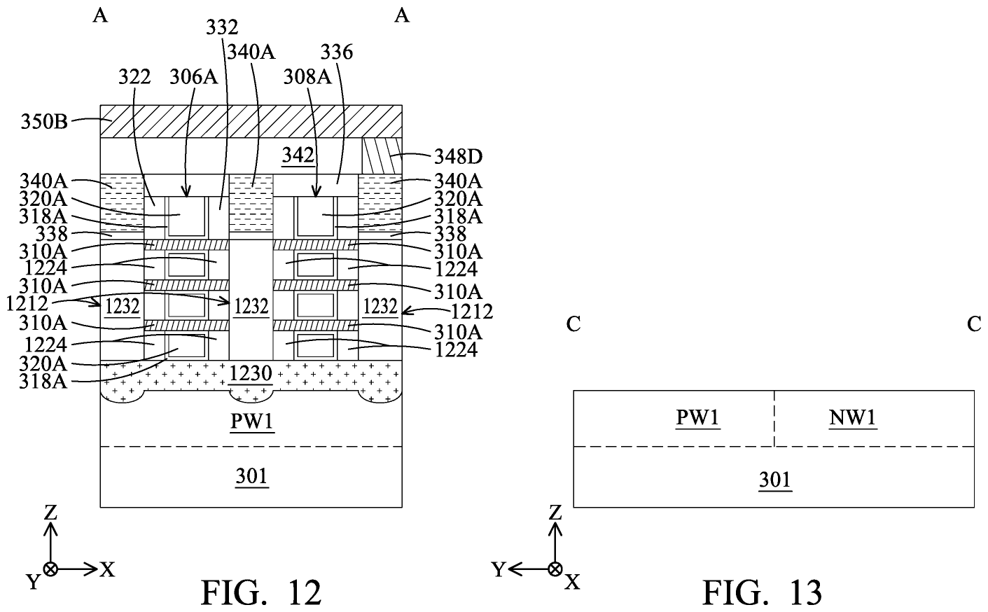

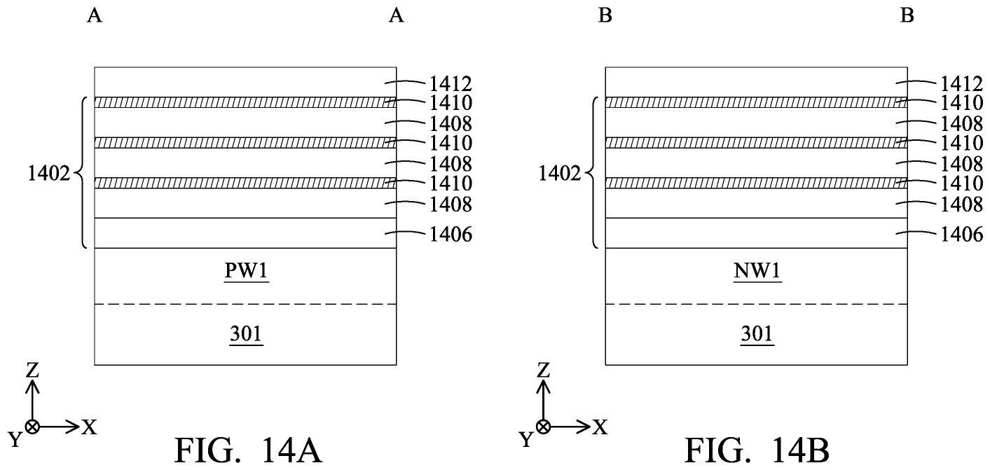

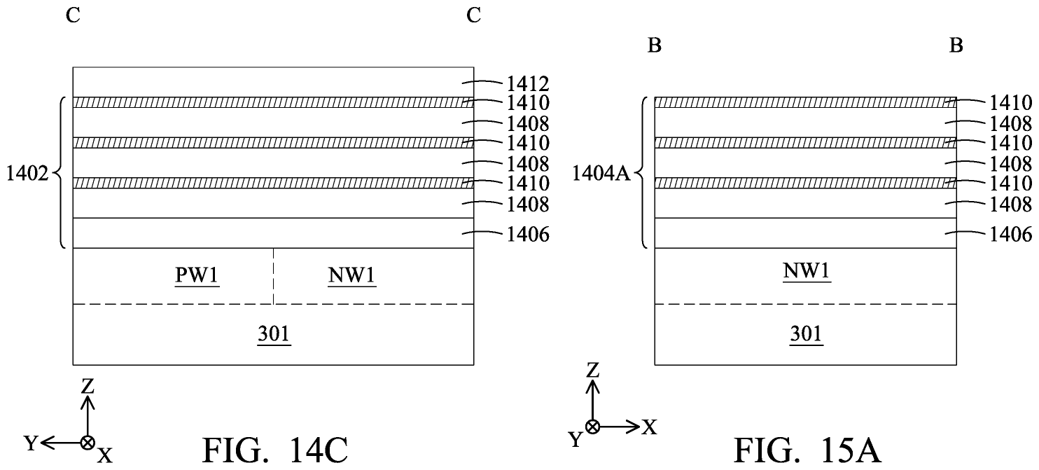

The following shows the formation of the semiconductor structure 300. FIGS. 14A to 26A are X-Z cross-sectional views of the semiconductor structure 300 at various fabrication stages along a line A-A of FIG. 4, in accordance with some embodiments of the present disclosure. FIGS. 14B to 26B are X-Z cross-sectional views of the semiconductor structure 300 at various fabrication stages along a line B-B of FIG. 4, in accordance with some embodiments of the present disclosure. FIGS. 13 and 14C to 26C are Y-Z cross-sectional views of the semiconductor structure 300 at various fabrication stages along a line C-C of FIG. 4, in accordance with some embodiments of the present disclosure.

Referring to FIG. 13, the substrate 301 is provided. In some embodiments, the substrate 301 is lightly doped with a p-type or an n-type dopant. An anti-punch-through (APT) implantation may be performed on an upper portion of the substrate 301 to form an APT region (not shown). During the APT implantation, dopants may be implanted in the substrate 301. The dopants may have a conductivity type that is the opposite of the conductivity type of the source/drain regions (e.g., the source/drain features 312, 314, 712, 714, 812, 814, 1012, 1014, 1112, and 1212) that will be subsequently formed on the well regions (e.g., the p-type well region PW1 and the n-type well region NW1). The APT region may extend under the subsequently formed source/drain regions in the resulting NMOSFET and PMOSFET. As described above, the existence of the bottom dielectric layers 330 (including the bottom dielectric layers 330, 630, 930, 1030, 1130, and 1230) can reduce the need for an APT process. Therefore, in some embodiments, the doping concentration of the APT implantation is reduced, alternatively, in other embodiments, the APT implantation is omitted.

In some embodiments, the p-type well region PW1 and the n-type well region NW1 are formed in or on the substrate 301, in accordance with some embodiments. In other embodiments, the substrate 301 may be formed to include other well regions, such as one or more other n-type well regions and/or p-type well regions. The materials and methods used in forming the substrate 301 and the various well regions (e.g., p-type well region PW1 and n-type well region NW1) have been discussed above, and are not repeated herein.

Referring to FIGS. 14A-14C, a stack 1402 is formed over the substrate 301 (e.g., the p-type well region PW1 and the n-type well region NW1), in accordance with some embodiments. In some embodiments, the stack 1402 includes a semiconductor layer 1406, semiconductor layers 1408, and semiconductor layers 1410. In some embodiments, the semiconductor layer 1406 is formed over the substrate 301, and the semiconductor layers 1408 and the semiconductor layers 1410 are alternatingly stacked over the semiconductor layer 1406 in the Z-direction. The semiconductor layer 1406, the semiconductor layers 1408, and the semiconductor layers 1410 may have different semiconductor compositions. In some embodiments, the semiconductor layer 1406 and the semiconductor layers 1408 are formed of silicon germanium (SiGe), and the semiconductor layers 1410 are formed of silicon (Si). In these embodiments, the additional germanium content in the semiconductor layer 1406 and the semiconductor layers 1408 allows selective removal or recess of the semiconductor layer 1406 and the semiconductor layers 1408 without substantial damages to the semiconductor layers 1410. In some embodiments, the semiconductor layer 1406 functions as a placeholder of the bottom dielectric layer that will be subsequently formed, and the semiconductor layers 1408 are also referred to as sacrificial layers.

In some embodiments, the semiconductor layer 1406 is Si₁₋ₓGeₓ, where x is in a range from about 0.35 to about 0.6, and the semiconductor layers 1408 are Si_{1-y}Ge_{y}, where y is in a range from about 0.1 to about 0.35. That is, the Ge concentration of the semiconductor layer 1406 is in a range from about 35% to about 60%, and the Ge concentration of the semiconductor layer 1408 is in a range from about 10% to about 35%. In these embodiments, the different germanium contents in the semiconductor layer 1406 and the semiconductor layers 1408 allow selective removal or recess of the semiconductor layer 1406 without substantial damages to the semiconductor layers 1408. In some embodiments, the etching rate ratio of the semiconductor layer 1406 and the semiconductor layer 1408 is greater than 20:1. In some embodiments, the etching rate ratio of the semiconductor layer 1408 and the semiconductor layer 1410 is greater than 20:1.

In some embodiments, the semiconductor layer 1406, the semiconductor layers 1408, and the semiconductor layers 1410 are epitaxially grown over or on the substrate 301 using an epitaxial growth such as VPE, MOCVD, MBE, although other deposition processes, such as CVD, LPCVD, PECVD, ALD, UHVCVD, RPCVD, a combination thereof, or the like, may also be utilized. The semiconductor layers 1408 and the semiconductor layers 1410 are deposited alternately, one-after-another, to form the stack. In some embodiments, the semiconductor layer 1406 has a thickness in the Z-direction that is in a range from about 3 nm to about 30 nm. In some embodiments, each of the semiconductor layers 1408 has a thickness in the Z-direction that is in a range from about 4 nm to about 15 nm.

For patterning purposes, the stack 1402 may further include a hard mask layer 1412 over the topmost semiconductor layer (e.g., the semiconductor layer 1408 or 1410). The hard mask layer 1412 may be a single layer structure or a multi-layer structure. In some embodiments, the hard mask layer 1412 is a single layer structure and includes a silicon germanium layer. In some embodiments, the hard mask layer 1412 is a multi-layer structure and includes a silicon nitride layer and a silicon oxide layer over the silicon nitride layer. In other embodiments, the hard mask layer 1412 is a multi-layer structure and includes a silicon germanium layer and a silicon layer over the silicon germanium layer.

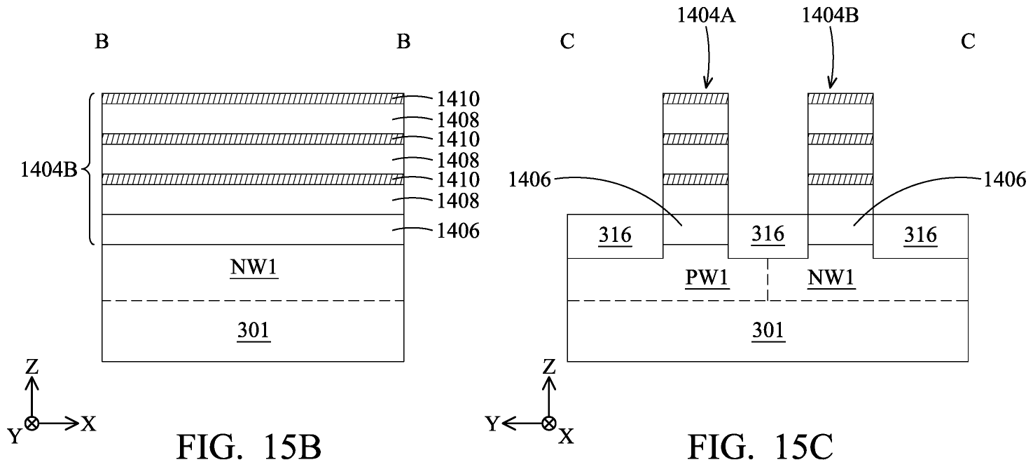

Referring to FIGS. 15A-15C, the substrate 301, the stack 1402, and the hard mask layer 1412 are then patterned to form a fin structure 1404A and a fin structure 1404B over the p-type well region PW1 and the n-type well region NW1, respectively, in accordance with some embodiments. The fin structures 1404A and 1404B may be included in the active region 302 and 304, respectively. Each of the fin structures 1404A and 1404B includes the semiconductor layers 1408 and 1410 that are alternately stacked in the Z-direction and the semiconductor layer 1406.

Still referring to FIGS. 15A-15C, the isolation structures 316 are formed over the substrate 301 and between the fin structures 1404A and 1404B. After the fin structures 1404A and 1404B are formed, the hard mask layer 1412 over the fin structures 1404A and 1404B is removed and the isolation structure 316 is formed over the substrate 301. In some embodiments, a dielectric material for the isolation structure 316 is first deposited. Specifically, the dielectric material is deposited to cover the fin structures 1404A, 1404B and the substrate 301. In various embodiments, the dielectric material may be deposited using a deposition process, such as CVD, subatmospheric CVD (SACVD), FCVD, ALD, spin-on coating, and/or other suitable process. The deposited dielectric material is then thinned and planarized, for example by a chemical mechanical polishing (CMP) process, until top surfaces of the hard mask layer 1412 is exposed. The planarized dielectric material is further recessed by a dry etching process, a wet etching process, and/or a combination thereof to form the isolation structure 316. In some embodiments, the semiconductor layers 1406 in the fin structures 1404A and 1404B are surrounded by the isolation structures 316, as shown in FIG. 15C. In some embodiments, before the formation of the isolation structure 316, a liner layer may be conformally deposited over the substrate 301 using a deposition process, such as CVD, ALD, HDPCVD, MOCVD, RPCVD, PECVD, LPCVD, ALCVD, APCVD, FCVD, or combinations thereof. The material of the isolation structures 316 has been discussed above, and are not repeated herein.

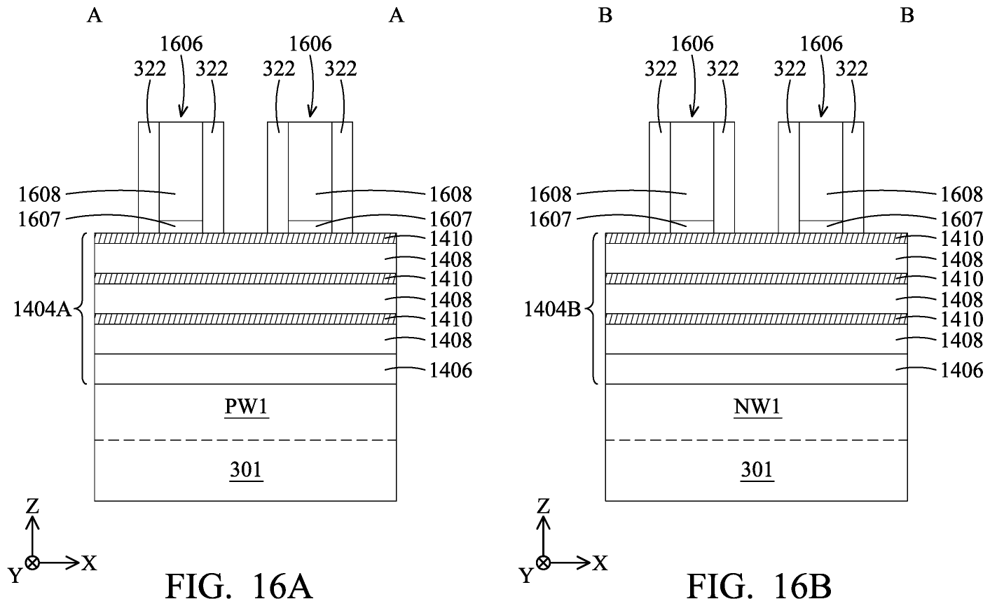

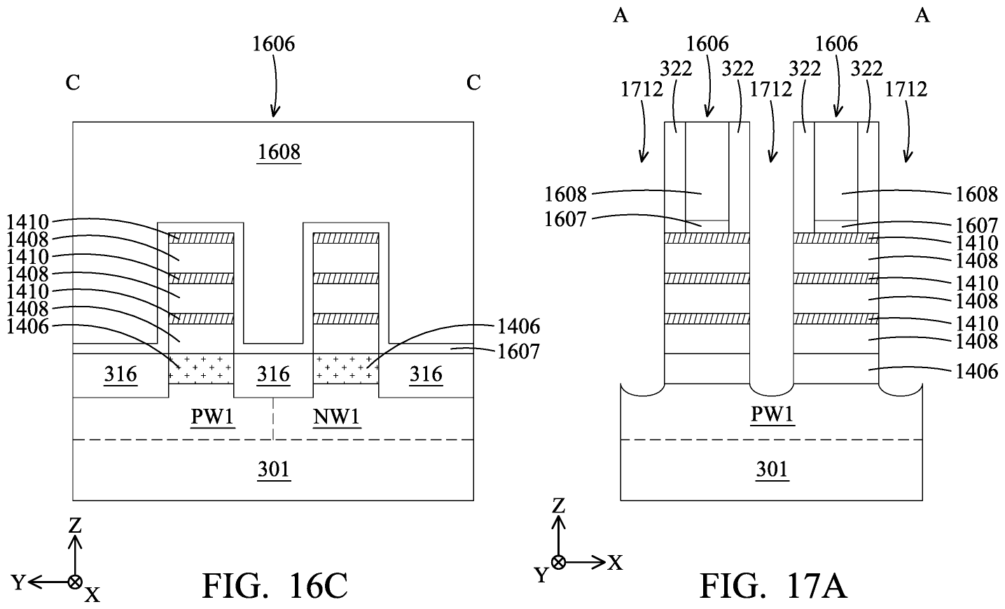

Referring to FIGS. 16A-16C, dummy gate structures 1606 are formed over the fin structures 1404A and 1404B, in accordance with some embodiments. In some embodiments, to form the dummy gate structures 1606, a dummy gate dielectric material for dummy gate dielectric layers 1607 is first formed over the fin structures 1404A and 1404B. In some embodiments, the dummy gate dielectric layers 2307 may include, for example, a dielectric material such as a nitride (e.g., silicon nitride, silicon oxynitride), a carbide (e.g., silicon carbide), an oxide (e.g., silicon oxide), or some other suitable material. Then, in some embodiments, a dummy gate electrode material for dummy gate electrodes 1608 is formed over the dummy gate dielectric material. The dummy gate electrode material may include a conductive material selected from a group comprising of polysilicon, W, Al, Cu, AlCu, Ti, TiAlN, TaC, TaCN, TaSiN, Mn, Zr, TiN, Ta, TaN, Co, Ni, and/or a combination thereof. The dummy gate electrode material and/or the dummy gate dielectric material may be formed by way of a thermal oxidation process and/or a deposition process (e.g., PVD, CVD, PECVD, and ALD).

After the formation of the dummy gate dielectric material and the dummy gate electrode material, one or more etching processes may be performed to pattern the dummy gate electrode material for the dummy gate electrodes 1608 and the dummy gate dielectric material for the dummy gate dielectric layers 1607, thereby forming the dummy gate structures 1606 each having the dummy gate dielectric layer 1607 and the dummy gate electrode 1608. The dummy gate structures 1606 may undergo a gate replacement process through subsequent process to form metal gates (e.g., the gate structures 306A, 306B, 308A, and 308B), such as a high-k metal gate, as discussed in greater detail below.

Still referring to FIGS. 16A-16C, after forming the dummy gate structures 1606, the gate spacers 322 are formed on sidewalls of the dummy gate structures 1606 and over the top surfaces of the fin structures 1404A and 1404B. More specifically, the gate spacers 322 are formed on opposite sidewalls of the dummy gate structures 1606. In some embodiments, the gate spacers 322 may be formed by conformally depositing a spacer layer (containing the dielectric material) over the fin structures 1404A, 1404B and dummy gate structures 1606, followed by an anisotropic etching process to remove top portions of the spacer layer from the top surfaces of the fin structures 1404A, 1404B and dummy gate structures 1606. After the anisotropic etching process, portions of the spacer layer on the sidewall surfaces of the fin structures 1404A, 1404B and the dummy gate structures 1606 substantially remain and become the gate spacers 322. In some embodiments, the anisotropic etching process is a dry (e.g., plasma) etching process. Additionally or alternatively, the formation of the gate spacers 322 may also involve chemical oxidation, thermal oxidation, CVD, PVD, ALD, HDPCVD, MOCVD, RPCVD, PECVD, LPCVD, ALCVD, APCVD, FCVD, and/or other suitable methods. The material of the gate spacers 322 have been discussed above, and are not repeated herein.

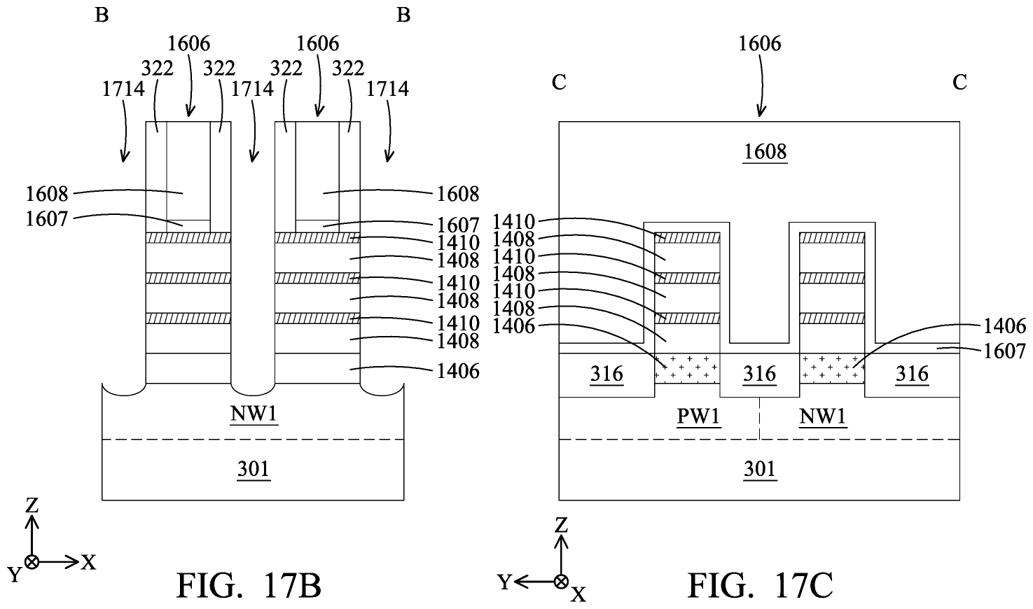

Referring to FIGS. 17A-17C, the fin structure 1404A is recessed to form source/drain trenches 1712 in the fin structure 1404A, and the fin structure 1404B is recessed to form source/drain trenches 1714 in the fin structure 1404B. In some embodiments, the source/drain trenches 1712 and 1714 are on opposite sides of the dummy gate structures 1606. Specifically, the source/drain trenches 1712 and 1714 may be formed by performing one or more etching processes to remove portions of the semiconductor layers 1406, the semiconductor layers 1408, the semiconductor layers 1410, and the substrate 301 that do not vertically overlap or be covered by the dummy gate structures 1606 and the gate spacers 322. In some embodiments, a single etchant may be used to remove the semiconductor layers 1406, the semiconductor layers 1408, the semiconductor layers 1410, and the substrate 301. In other embodiments, multiple etchants may be used to perform the etching process.

In some embodiments, portions of the substrate 301 are etched, as shown in FIGS. 17A and 17B. In other words, the source/drain trenches 1712 and 1714 extend into the substrate 301 (i.e., into the p-type well region PW1 and the n-type well region NW1, respectively), so that bottom surfaces of the source/drain trenches 1712 and 1714 are lower than the topmost surfaces of the substrate 301. In some embodiments, the source/drain trenches 1712 and 1714 extend into the substrate 301 by a depth that is in a range from about 5 nm to about 30 nm.

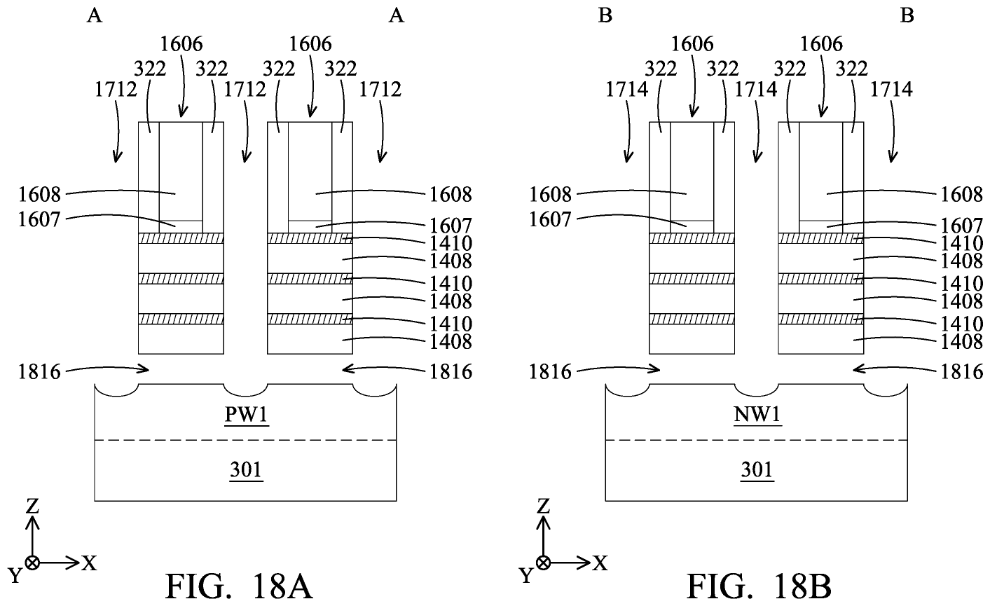

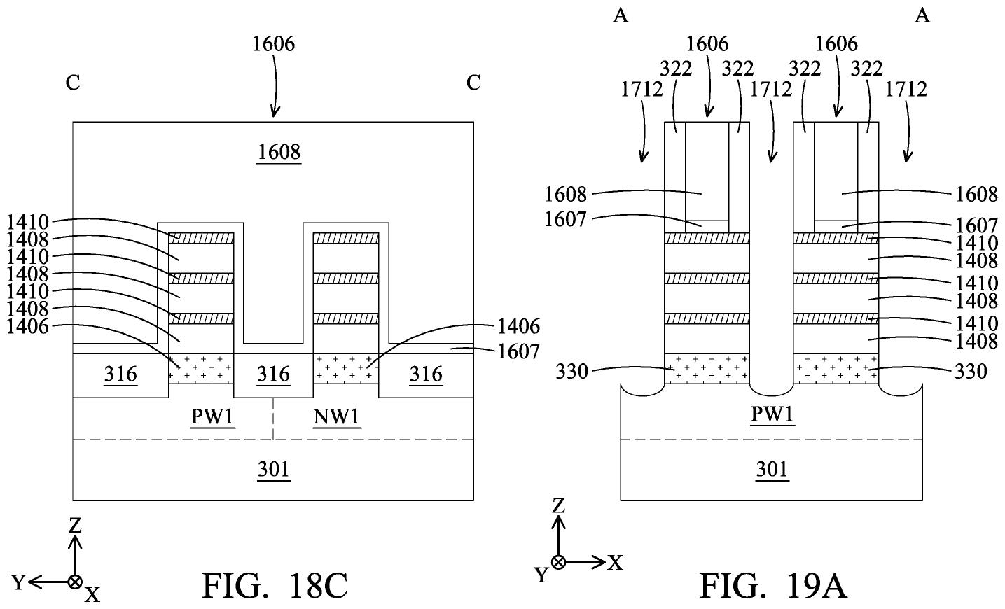

Referring to FIGS. 18A-18C, the semiconductor layers 1406 exposed in the source/drain trenches 1712 and 1714 are removed by a selective etching process, in accordance with some embodiments. Specifically, the selective etching process is performed that selectively etches the semiconductor layers 1406 through the source/drain trenches 1712 and 1714, with minimal etching (or substantially no etching) of the semiconductor layers 1408 and the semiconductor layers 1410. After the selective etching process, recesses 1816 are formed under the dummy gate structures 1606, between the source/drain trenches 1712 or 1714, and between the bottommost semiconductor layers 1408 and the substrate 301 (e.g., the p-type well region PW1 or the n-type well region NW1). The selective etching process is configured to laterally etch (e.g., along the X-direction) the semiconductor layers 1406. The selective etching process may be a dry etching process, a wet etching process, other suitable etching process, or combinations thereof.

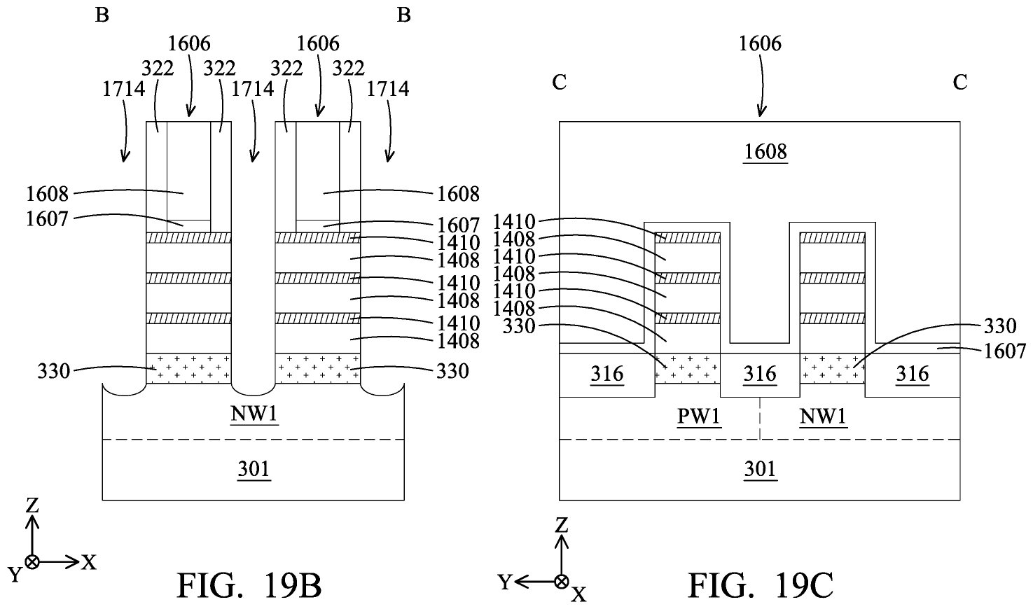

Referring to FIGS. 19A-19C, the bottom dielectric layers 330 are formed in the recesses 1816 to fill the recesses 1816, in accordance with some embodiments. In some embodiments, sidewalls of the bottom dielectric layers 330 are aligned to the sidewalls of the gate spacers 322, the semiconductor layers 1408, and the semiconductor layers 1410. In other embodiments, sidewalls of the bottom dielectric layers are aligned to the sidewalls of the dummy gate electrodes 1608.

In order to form the bottom dielectric layers 330, a deposition process is performed to form a dielectric material layer into the source/drain trenches 1712 and 1714 and the recesses 1816. For example, the deposition process may be CVD, PVD, ALD, HDPCVD, MOCVD, RPCVD, PECVD, LPCVD, ALCVD, APCVD, other suitable methods, or combinations thereof. The dielectric material layer partially (and, in some embodiments, completely) fills the source/drain trenches 1712 and 1714. The deposition process is configured to ensure that the dielectric material layer fills the recesses 1816 between the bottommost semiconductor layers 1408 and the substrate 301 under the dummy gate structures 1606. An etching back process is then performed that selectively etches the dielectric material layer to form bottom dielectric layers 330 with minimal etching (or substantially no etching) of the semiconductor layers 1408, the semiconductor layers 1410, the substrate 301, the dummy gate structures 1606, and the gate spacers 322. The material and the dimension of the bottom dielectric layer 330 have been discussed above, and are not repeated herein.

In other embodiments, the etching back process is configured to selectively etch the dielectric material layer and remain less material layer. In these embodiments, after the etching back process, the remaining dielectric material layer partially fills the recesses 1816 and forms bottom dielectric layers that are smaller than the bottom dielectric layers 330 in the X-direction. In these embodiments, bottom dielectric layers such as the bottom dielectric layers 930 shown in FIGS. 9A and 9B are formed. In these embodiments, there are still small recesses remained between the bottom dielectric layers and the source/drain trenches 1712/1714, and these small recesses are filled with the material of inner spacers in the process of forming the inner spacers. In these embodiments, inner spacers such as the inner spacers 924 shown in FIGS. 9A and 9B are formed.

In certain embodiments, in the p-type well region PW1, the etching back process is configured to selectively etch the dielectric material layer and remain more material layer. In these embodiments, after the etching back process, the remaining dielectric material layer fills the recesses 1816 and partially fills the source/drain trenches 1712 and 1714, such as fills the bottom portions of the source/drain trenches 1712 and 1714, such that the formed bottom dielectric layers are greater than the bottom dielectric layers 330 in the X-direction and cover the bottom portions of the source/drain trenches 1712 and 1714. In these embodiments, bottom dielectric layers such as the bottom dielectric layers 1130 shown in FIG. 11 are formed.

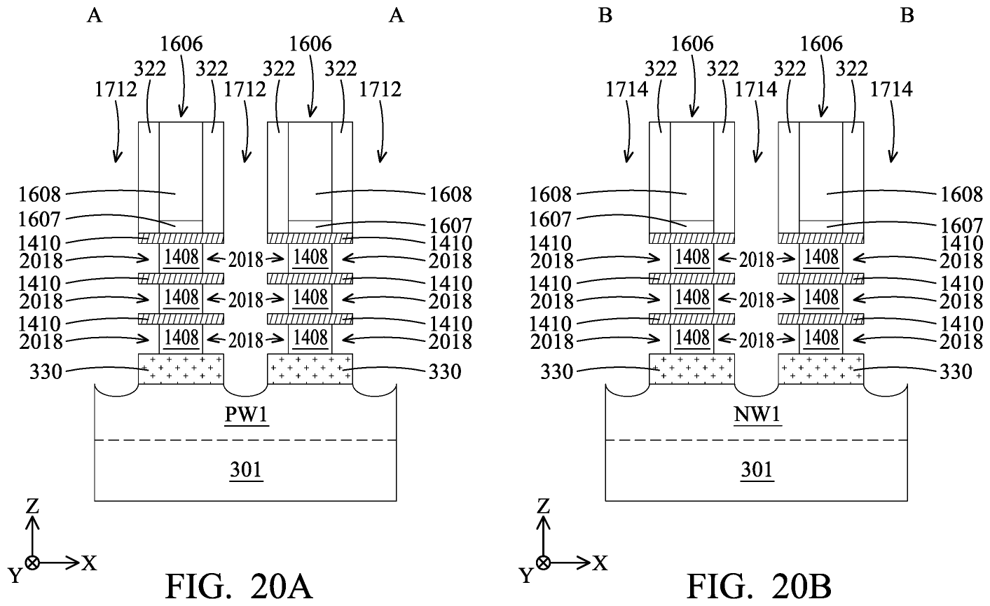

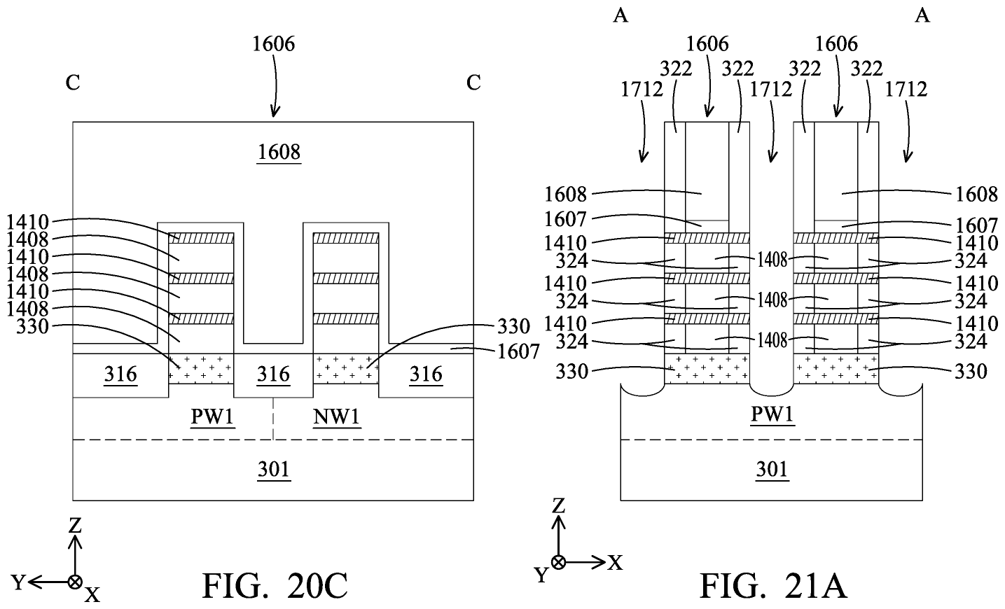

Referring to FIGS. 20A-20C, the semiconductor layers 1408 exposed in the source/drain trenches 1712 and 1714 are partially recessed by a selective etching process, in accordance with some embodiments. Specifically, the selective etching process is performed that selectively etches the side portions of the semiconductor layers 1408 below the gate spacers 322 through the source/drain trenches 1712 and 1714, with minimal etching (or substantially no etching) of the semiconductor layers 1410, and the bottom dielectric layers 330. After the selective etching process, inner spacer recesses 2018 are formed between the semiconductor layers 1410 as well as between the semiconductor layers 1410 and the bottom dielectric layers 330 that is over the substrate 301, and below the gate spacers 322. The selective etching process is configured to laterally etch (e.g., along the X-direction) the semiconductor layers 1408 below the gate spacers 322. The selective etching process may be a dry etching process, a wet etching process, other suitable etching process, or combinations thereof.

In some embodiments, each of the inner spacer recess 2018 has a width in the X-direction that is in a range from about 2 nm to about 12 nm. In some embodiments, the semiconductor layers 1410 are also etched during the selective etching process, and the inner spacer recesses 2018 partially extend in the Z-direction into the semiconductor layers 1410. In some embodiments, the semiconductor layers 1410 include curved top surfaces and curved bottom surface exposed by the inner spacer recesses 2018.

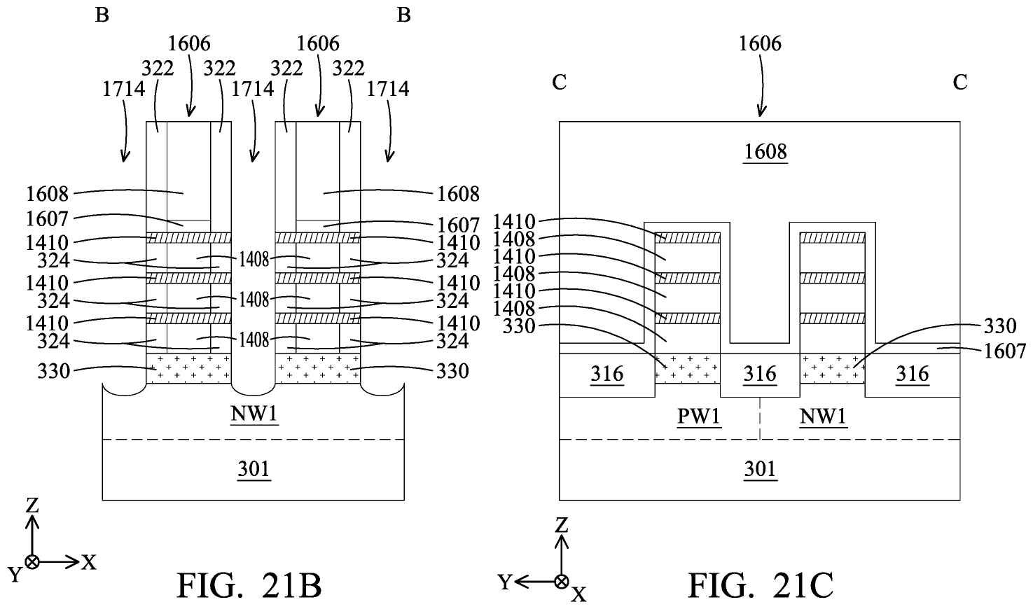

Referring to FIGS. 21A-21C, inner spacers 324 are formed in the inner spacer recesses 2018 to fill the inner spacer recesses 2018, in accordance with some embodiments. In some embodiments, sidewalls of the inner spacers 324 are aligned to the sidewalls of the gate spacers 322 and the semiconductor layers 1410. In some other embodiments, sidewalls of the inner spacers 324 have concave surfaces exposed by the source/drain trenches 1712 and 1714.

In order to form the inner spacers 324, a deposition process is performed to form a spacer layer into the source/drain trenches 1712 and 1714 and the inner spacer recesses 2018. For example, the deposition process may be CVD, PVD, ALD, HDPCVD, MOCVD, RPCVD, PECVD, LPCVD, ALCVD, APCVD, other suitable methods, or combinations thereof. The spacer layer partially (and, in some embodiments, completely) fills the source/drain trenches 1712 and 1714. The deposition process is configured to ensure that the spacer layer fills the inner spacer recesses 2018 between the semiconductor layers 1410 as well as between the semiconductor layer 1410 and the substrate 301 under the gate spacers 322. An etching process is then performed that selectively etches the spacer layer to form inner spacers 324 (as shown in FIGS. 21A-21C) with minimal etching (or substantially no etching) of the semiconductor layers 1410, the substrate 301, the dummy gate structures 1606, and the gate spacers 322. The material and the dimension of the inner spacers 324 have been discussed above, and are not repeated herein.

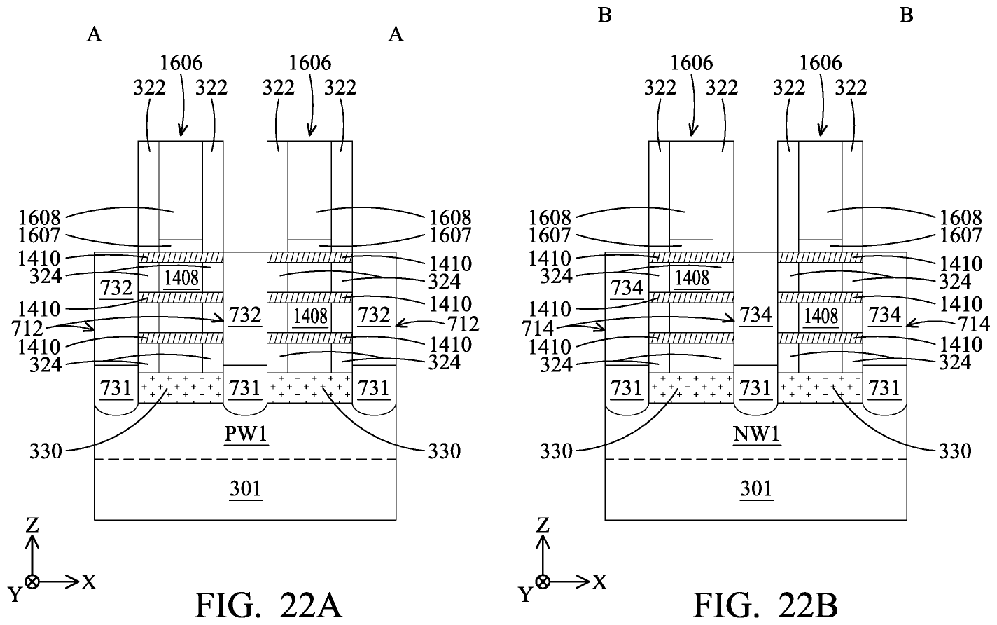

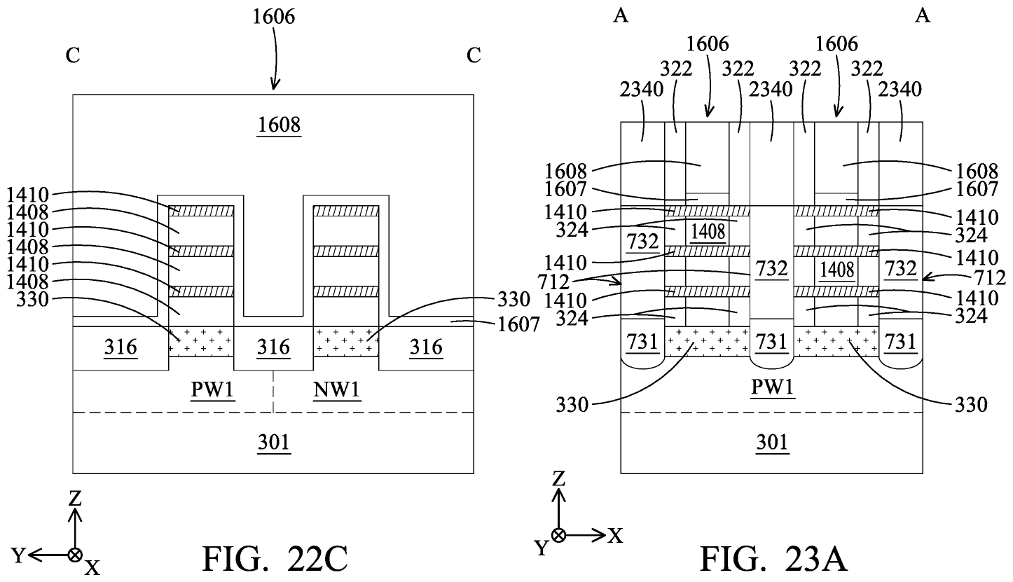

Referring to FIGS. 22A-22C, the undoped epitaxial layers 731 are formed in bottom portions of the source/drain trenches 1712 and 1714, in accordance with some embodiments. The material and the method of forming the undoped epitaxial layers 731 have been discussed above, and are not repeated herein.

Still referring to FIGS. 22A-22C, the doped epitaxial layers 732 are formed in each of the source/drain trenches 1712 and the doped epitaxial layers 734 are formed in each of the source/drain trenches 1714, thereby forming the source/drain features 712 and the source/drain features 714, respectively, in accordance with some embodiments. The materials and methods used in forming the doped epitaxial layers 732 and 734 have been discussed above, and are not repeated herein. In some embodiments, each of the source/drain features 712 includes the undoped epitaxial layer 731 over the p-type well region PW1, and the doped epitaxial layer 732 over the undoped epitaxial layer 731, as shown in FIG. 22A. In some embodiments, each of the source/drain features 714 includes the undoped epitaxial layer 731 over the n-type well region NW1 and the doped epitaxial layer 734 over the undoped epitaxial layer 731, as shown in FIG. 22B.

In some embodiments, the formation of the undoped epitaxial layers 731 is omitted, such that the doped epitaxial layers 732 and 734 are in direct contact with the p-type well region PW1 and the n-type well region NW1, respectively. In these embodiments, the resulting source/drain features are the same as or similar to the source/drain features 312, 314, 1012, and 1014 shown in FIGS. 5A, 5B, 10A, and 10B.

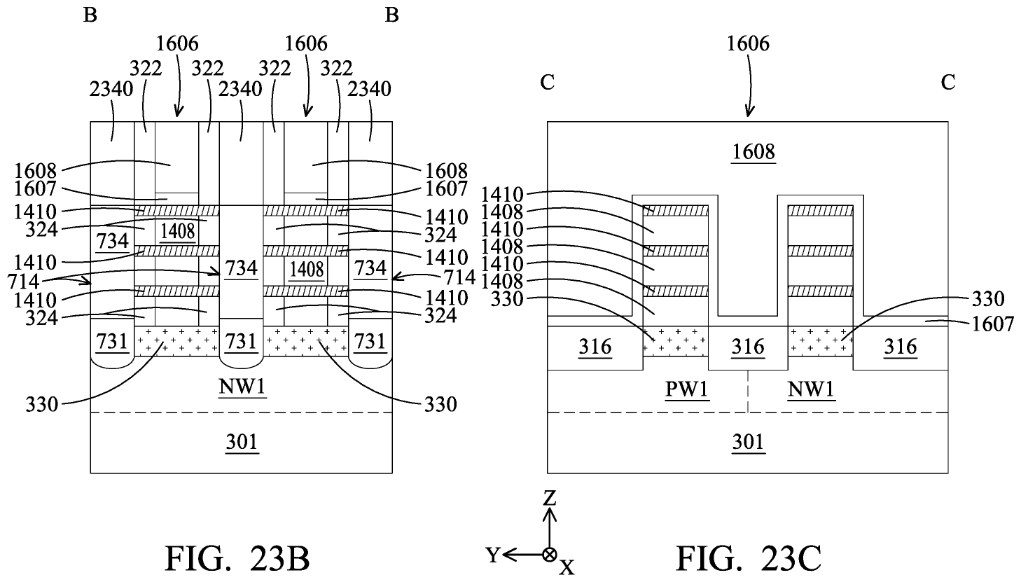

Referring to FIGS. 23A-23C, an ILD layer 2340 is formed to fill the space between the gate spacers 322, in accordance with some embodiments. The ILD layer 2340 may include tetraethylorthosilicate (TEOS) formed oxide, un-doped silicate glass, or doped silicon oxide such as BPSG, FSG, PSG, BSG, a low-k dielectric material, other suitable dielectric material, or combinations thereof. The ILD layer 2340 may be formed by CVD, PVD, ALD, HDPCVD, MOCVD, RPCVD, PECVD, LPCVD, ALCVD, APCVD, FCVD, or other suitable methods. Subsequent to the formation of the ILD layer 2340, a CMP process and/or other planarization process is performed on the ILD layer 2340 until the top surfaces of the dummy gate structures 1606 are exposed. In some embodiments, portions of the dummy gate electrodes 1608 and the gate spacers 322 are removed after the planarization process.

In some embodiments, before the formation of the ILD layer 2340, a contact etch stop layer (CESL) may be conformally formed on the sidewalls of the gate spacers 322 and over the top surfaces of the source/drain features 712 and 714. The ILD layer 2340 is then formed over and between the CESL to fill the space between the CESL. The CESL includes a material that is different than ILD layer 2340. The CESL may include La₂O₃, Al₂O₃, SiOCN, SiOC, SiCN, SiO₂, SiC, ZnO, ZrN, Zr₂Al₃O₉, TiO₂, TaO₂, ZrO₂, HfO₂, Si₃N₄, Y₂O₃, AlON, TaCN, ZrSi, or other suitable material(s), and may be formed by CVD, PVD, ALD, HDPCVD, MOCVD, RPCVD, PECVD, LPCVD, ALCVD, APCVD, FCVD, or other suitable methods.

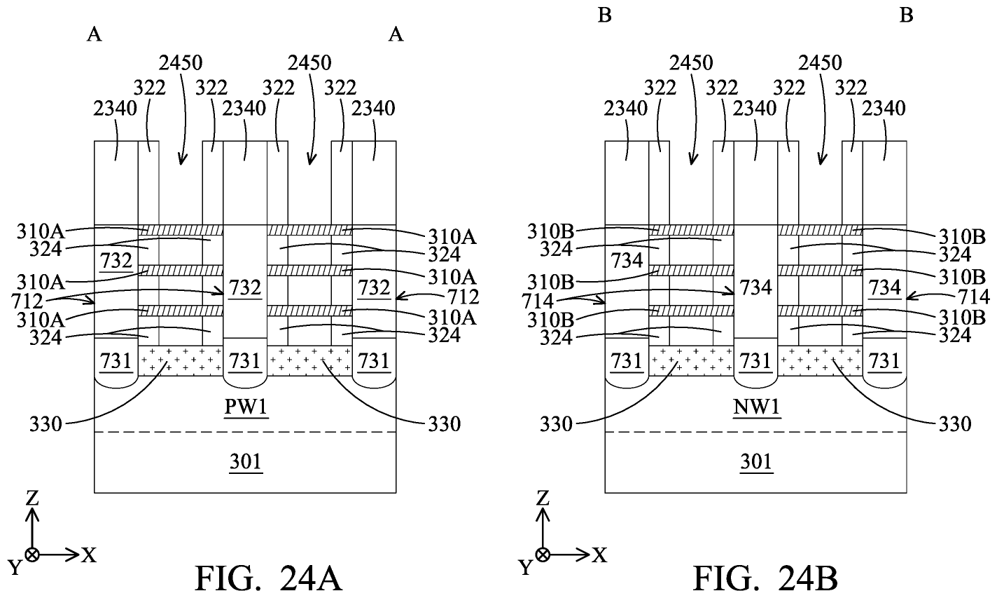

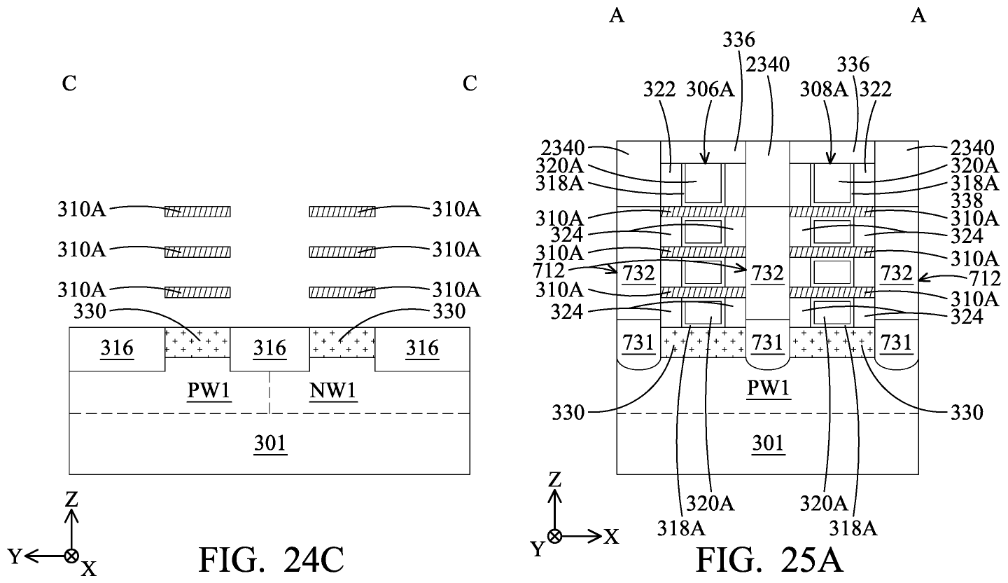

Referring to FIGS. 24A-24C, the dummy gate structures 1606 are selectively removed through any suitable lithography and etching processes, in accordance with some embodiments. In some embodiments, the lithography process may include forming a photoresist layer (resist), exposing the resist to a pattern, performing a post-exposure bake process, and developing the resist to form a masking element, which exposes the region including the dummy gate structures 1606. Then, the dummy gate structures 1606 are selectively etched through the masking element. Etch selectivity may be achieved by selecting the appropriate etching chemicals, and the dummy gate structures 1606 may be removed without substantially affecting the gate spacers 322, the inner spacers 324, and the substrate 301. The removal of the dummy gate structures 1606 creates gate trenches 2450. The gate trenches 2450 expose the top surfaces of the topmost semiconductor layers 1410 underlies the dummy gate structures 1606.

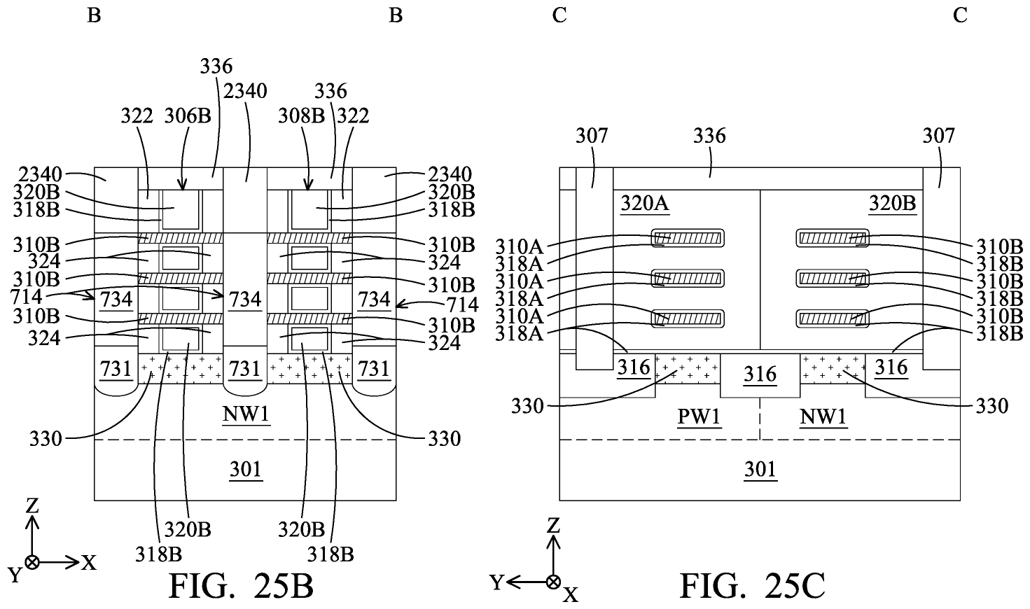

Still referring to FIGS. 25A-25C, the semiconductor layers 1408 are selectively removed through the gate trenches 2450, using a wet or dry etching process for example, in accordance with some embodiments. After the semiconductor layers 1408 are selectively removed, the semiconductor layers 1410 are exposed in the gate trenches 2450 to form the nanostructures 310A and 310B. Such a process may also be referred to as a wire release process, a nanowire release process, a nanosheet release process, a nanowire formation process, a nanosheet formation process, or a nanowire formation process. The configurations of the nanostructures 310A and 310B have been discussed above, and are not repeated herein.

Referring to FIGS. 25A-25C, the gate structures 306A, 306B, 308A, and 308B discussed above are formed in the gate trenches 2450, in accordance with some embodiments. In some embodiments, the gate structures 306A, 306B, 308A, and 308B wrap around each of the semiconductor layers 1410, that is, wrap around each of the nanostructures 310A and 310B. In some embodiments, the gate structure 306A wraps around each of nanostructures 310A in corresponding vertical stack, the gate structure 308A wraps around each of nanostructures 310A in corresponding vertical stack, the gate structure 306B wraps around each of nanostructures 310B in corresponding vertical stack, and the gate structure 308B wraps around each of nanostructures 310B in corresponding vertical stack.

In some embodiments, the gate structures 306A and 308A each has the gate dielectric layer 318A and the gate electrode layer 320A. The gate dielectric layers 318A wrap around each of the nanostructures 310A, and the gate electrode layers 320A wrap around the gate dielectric layer 318A. In some embodiments, the gate structures 306B and 308B each has the gate dielectric layer 318B and the gate electrode layer 320B. The gate dielectric layers 318B wrap around each of the nanostructures 310B, and the gate electrode layers 320B wrap around the gate dielectric layer 318B. In some embodiments, the gate dielectric layers 318A and 318B are also formed on sidewalls of the inner spacers 324 and the gate spacers 322. The materials and methods used in forming the gate dielectric layers 318A, 318B and the gate electrode layers 320A, 320B have been discussed above, and are not repeated herein.

Still referring to FIGS. 25A-25C, after forming the gate structures 306A, 306B, 308A, and 308B, portions of the gate structures 306A, 306B, 308A, and 308B and the gate spacers 322 are recessed, and the gate top dielectrics 336 discussed above are formed over the gate structures 306A, 306B, 308A, and 308B and the gate spacers 322.

Still referring to FIGS. 25A-25C, gate end dielectrics 307 and gate end dielectrics 309 (see FIG. 4) are formed in the gate structures 306A, 306B, 308A, and 308B, in accordance with some embodiments. The materials and methods used in forming the gate end dielectrics 307 and 309 have been discussed above, and are not repeated herein.

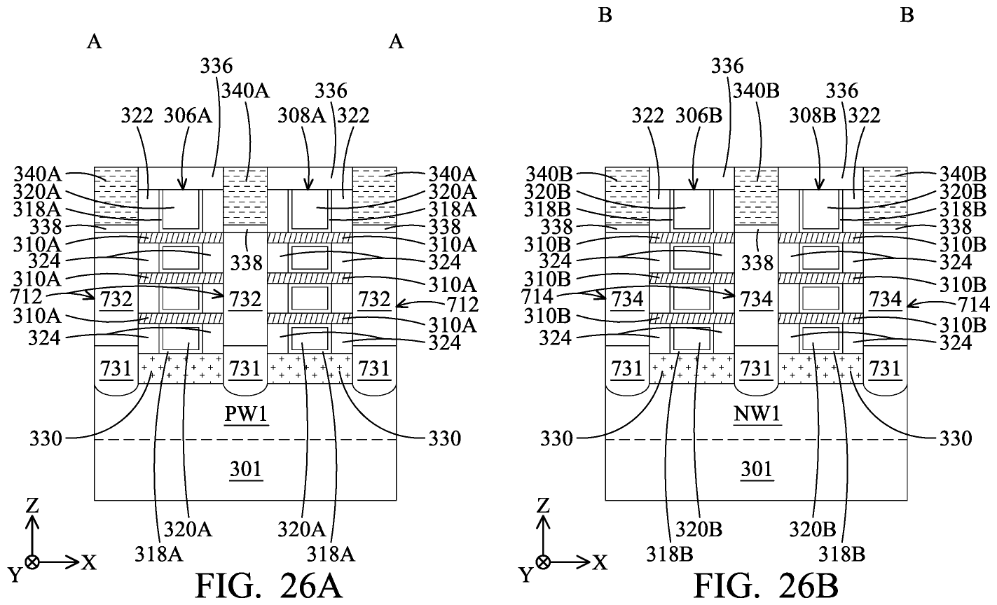

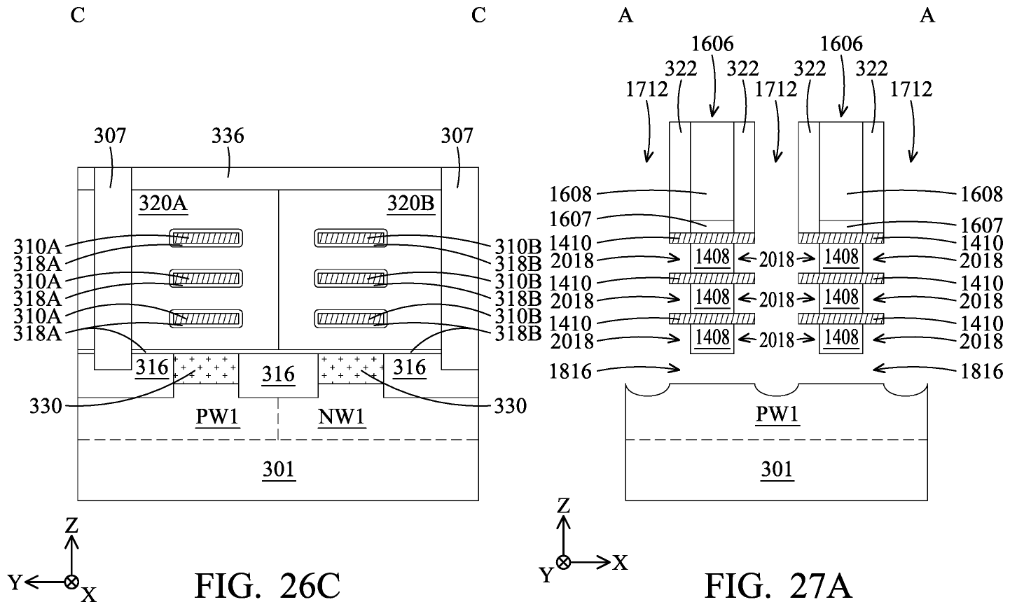

Referring to FIGS. 26A-26C, the source/drain contacts 340 discussed above are formed in the ILD layer 2340, in accordance with some embodiments. In some embodiments, the source/drain contacts 340A are over and electrically connected to the respective source/drain features 712. In some embodiments, two source/drain contacts 340A are on the opposite sides of the gate structure 306A, and two source/drain contacts 340A are on the opposite sides of the gate structure 308A. In some embodiments, the source/drain contacts 340B are over and electrically connected to the respective source/drain features 714. In some embodiments, two source/drain contacts 340B are on the opposite sides of the gate structure 306B, and two source/drain contacts 340B are on the opposite sides of the gate structure 308B. The materials and methods used in forming the source/drain contacts 340 have been discussed above, and are not repeated herein.

In some embodiments, additional features are formed between the source/drain features 712, 714 and the source/drain contacts 340, such as the silicide layers 338 discussed above. As such, the transistors in the semiconductor structure 300 are formed.

After the operation shown in FIGS. 26A-26C, the further processes may be performed to complete the semiconductor structure 300. After the further processes, the resulting structure may be the same as or similar to the structure shown in FIGS. 7A-7C. For example, the ILD layer 342 may be formed over the structure shown in FIGS. 26A-26C, and the gate vias 346A-346B and the source/drain vias 348A-348E may be formed in the ILD layer 342. For example, the IMD layer 344 may be formed over the ILD layer 342, and the metal layer M1 (e.g., the metal conductors 350A-350G) may be formed in the IMD layer 344.

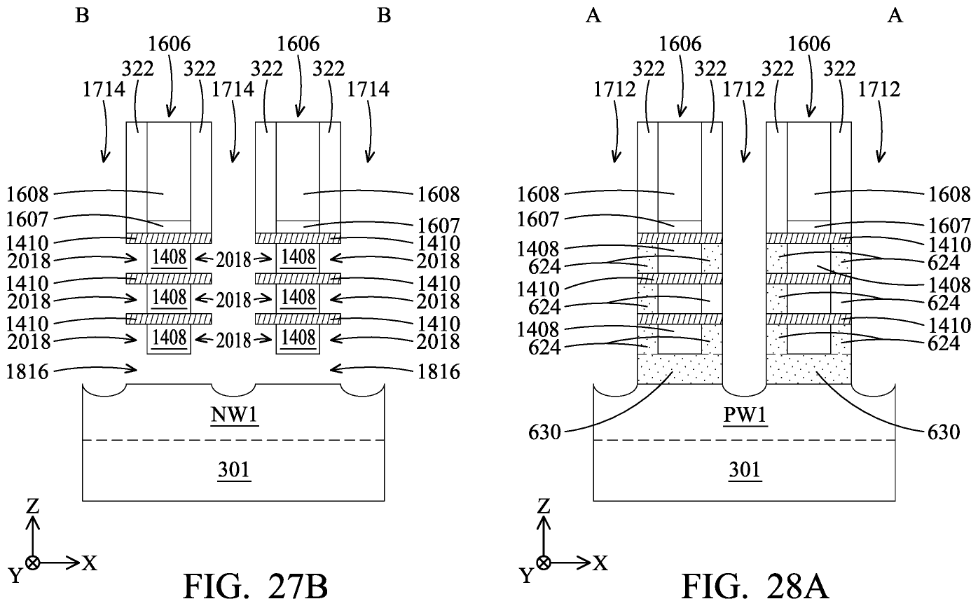

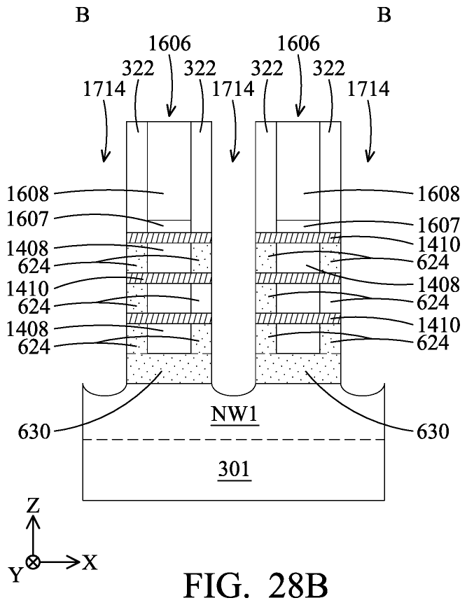

The following shows the formation of the semiconductor structure 300, in accordance with some alternative embodiments. FIGS. 27A and 28A are X-Z cross-sectional views of the semiconductor structure 300 at various fabrication stages along a line A-A of FIG. 4, in accordance with some alternative embodiments of the present disclosure. FIGS. 27B and 28B are X-Z cross-sectional views of the semiconductor structure 300 at various fabrication stages along a line B-B of FIG. 4, in accordance with some alternative embodiments of the present disclosure. The fabrication stage shown in FIGS. 27A and 27B follows the fabrication stage shown in FIGS. 18A-18C. After the fabrication stage shown in FIGS. 28A and 28B, the formation of the semiconductor structure 300 may proceed to the fabrication stage shown in FIGS. 22A-22C.

Referring to FIGS. 27A and 27B, the semiconductor layers 1408 exposed in the source/drain trenches 1712 and 1714 are partially recessed to form inner spacer recesses 2018, while the recesses 1816 are still not filled with material layer, in accordance with some embodiments. The method used in forming the inner spacer recesses 2018 has been discussed above, and are not repeated herein.

Referring to FIGS. 28A and 28B, inner spacers 624 and bottom dielectric layers 630 are formed in the inner spacer recesses 2018 and the recesses 1816 to fill the inner spacer recesses 2018 and the recesses 1816, in accordance with some embodiments. In some embodiments, sidewalls of the inner spacers 624 and the bottom dielectric layers 630 are aligned to the sidewalls of the gate spacers 322 and the semiconductor layers 1410. In some other embodiments, sidewalls of the inner spacers 624 and the bottom dielectric layers 630 have concave surfaces exposed by the source/drain trenches 1712 and 1714.

In order to form the inner spacers 624 and the bottom dielectric layers 630, a deposition process is performed to form a spacer layer into the source/drain trenches 1712 and 1714, the recesses 1816, and the inner spacer recesses 2018. For example, the deposition process may be CVD, PVD, ALD, HDPCVD, MOCVD, RPCVD, PECVD, LPCVD, ALCVD, APCVD, other suitable methods, or combinations thereof. The spacer layer partially (and, in some embodiments, completely) fills the source/drain trenches 1712 and 1714. The deposition process is configured to ensure that the spacer layer fills the recesses 1816 and the inner spacer recesses 2018. An etching back process is then performed that selectively etches the spacer layer to form inner spacers 624 and the bottom dielectric layers 630 (as shown in FIGS. 28A and 28B) with minimal etching (or substantially no etching) of the semiconductor layers 1410, the substrate 301, the dummy gate structures 1606, and the gate spacers 322. The materials and the dimensions of the inner spacers 624 and the bottom dielectric layers 630 have been discussed above, and are not repeated herein. As described above, in some embodiments, the bottom dielectric layers 630 may be considered as portions of the inner spacers 624.

In other embodiments, in the p-type well region PW1, the etching back process is configured to selectively etch the spacer layer and remain more spacer layer. In these embodiments, after the etching back process, the remaining spacer layer fills the recesses 1816 and the inner spacer recesses 2018, and partially fills the source/drain trenches 1712 and 1714, such as fills the bottom portions of the source/drain trenches 1712 and 1714, such that the formed bottom dielectric layers are greater than the bottom dielectric layers 630 in the X-direction and cover the bottom portions of the source/drain trenches 1712 and 1714. In these embodiments, bottom dielectric layers such as the bottom dielectric layers 1230 shown in FIG. 12 are formed.

The embodiments disclosed herein are related to semiconductor structures, and more particularly to semiconductor structures including MOSFETs with bottom dielectric layers formed below the gate structure and between the gate structure and underlying substrate. The present embodiments provide one or more of the following advantages. The bottom dielectric layer located below the gate structure can reduce the off-state drain-to-source leakage current Isoff, and reduce the capacitance between the gate structure and well region. Furthermore, the structure with source/drain (S/D) features having undoped epitaxial layer located on opposite of the bottom dielectric layer can reduce the S/D junction leakage and the S/D junction capacitance. Moreover, the provided structure with the bottom dielectric layer allows lower APT dosage or omitting the APT process, and thus the performance of threshold voltage (Vt) mismatch can be improved.

Thus, one of the embodiments of the present disclosure describes a semiconductor structure. The semiconductor structure includes a substrate; first nanostructures suspended over and vertically arranged over the substrate; a first gate structure wrapped around each of the first nanostructures; and gate spacers formed on opposite sides of the first gate structure and over a topmost one of the first nanostructures. The semiconductor structure further includes first source/drain features attached to opposite sides of the first nanostructures; and a first bottom dielectric layer formed over the substrate and below the first nanostructures. The first bottom dielectric layer is vertically sandwiched between the substrate and the first gate structure.

In some embodiments, the semiconductor structure further includes inner spacers formed on opposite sides of the first gate structure and separating the first nanostructures from each other. The first bottom dielectric layer is below the inner spacers and sandwiched between a bottommost pair of the inner spacers and the substrate.

In some embodiments, the semiconductor structure further includes inner spacers formed on opposite sides of the first gate structure and separating the first nanostructures from each other. The bottommost pair of the inner spacers extends downward in a vertical direction and contacts opposite sides of the first bottom dielectric layer.

In some embodiments, a thickness of the first bottom dielectric layer is in a range from about 3 nm to about 30 nm.

In some embodiments, each of the first source/drain features includes an undoped epitaxial layer and a doped epitaxial layer over the undoped epitaxial layer; and the first bottom dielectric layer is in contact with and between the undoped epitaxial layers.

In some embodiments, a top surface of the undoped epitaxial layer is higher than a top surface of the first bottom dielectric layer and lower than a bottom surface of a bottommost one of the first nanostructures.

In some embodiments, the first bottom dielectric layer extends in a horizontal direction; and the first source/drain features partially cover a top surface of the first bottom dielectric layer.

In some embodiments, the semiconductor structure further includes second nanostructures suspended over and vertically arranged over the substrate; a second gate structure wrapped around each of the second nanostructures; second source/drain features attached to opposite sides of the second nanostructures; and a second bottom dielectric layer formed over the substrate and below the second gate structure and the second source/drain features. The second bottom dielectric layer is sandwiched between the second gate structure and the substrate and sandwiched between the second source/drain features and the substrate. The first source/drain features are in direct contact with the substrate.

In some embodiments, the first source/drain features are p-type source/drain features, and the second source/drain features are n-type source/drain features.

In some embodiments, the first nanostructures, the first gate structure, the first source/drain features, and the first bottom dielectric layer are formed on an n-type well region, and the second nanostructures, the second gate structure, the second source/drain features, and the second bottom dielectric layer are formed on a p-type well region.

In another of the embodiments, discussed is a semiconductor structure that includes a substrate; first nanostructures suspended over and vertically arranged over the substrate in a Z-direction; a first gate structure extending in a Y-direction and wrapped around each of the first nanostructures; and first source/drain features attached to opposite sides of the first nanostructures in an X-direction. The semiconductor structure further includes first inner spacers formed on opposite sides of the first gate structure in the X-direction and between the first nanostructure in the Z-direction; and a first bottom dielectric layer formed below the first gate structure in the Z-direction and connected to a bottommost pair of the first inner spacers. The first bottom dielectric layer is in contact with the first gate structure and separates the first gate structure form the substrate in the Z-direction.

In some embodiments, each of the first source/drain features includes an undoped epitaxial layer and a doped epitaxial layer over the undoped epitaxial layer in the Z-direction; and the first bottom dielectric layer is in contact with and between the undoped epitaxial layers in the X-direction.

In some embodiments, the semiconductor structure further includes gate spacers formed on opposite sides of the first gate structure in the X-direction and over a topmost one of the first nanostructures in the Z-direction. A width of each of the gate spacers is greater than a width of each of the first inner spacers in the X-direction.

In some embodiments, the first inner spacers and the first bottom dielectric layer are formed of the same material.

In some embodiments, the semiconductor structure further includes second nanostructures suspended over and vertically arranged over the substrate in the Z-direction; a second gate structure extending in the Y-direction and wrapped around each of the second nanostructures; and second source/drain features, attached to opposite sides of the second nanostructures in the X-direction. The semiconductor structure further includes second inner spacers formed on opposite sides of the second gate structure in the X-direction and between the second nanostructures in the Z-direction; and a second bottom dielectric layer formed below the second gate structure and the second source/drain features in the Z-direction, and connected to a bottommost pair of the second inner spacers. The second bottom dielectric layer separated the second source/drain features from the substrate in the Z-direction. The first source/drain features are in direct contact with opposite sides of the first bottom dielectric layer in the X-direction.

In some embodiments, the first source/drain features are p-type source/drain features, and the second source/drain features are n-type source/drain features.

In yet another of the embodiments, discussed is a method of forming a semiconductor structure. The method includes forming a fin structure over a substrate; forming a dummy gate structure over the fin structure; and forming source/drain trenches in the fin structure on opposite sides of the dummy gate structure. The fin structure includes a first semiconductor layer over the substrate, and second semiconductor layers and third semiconductor layers alternately stacked over the first semiconductor layer. The method further includes removing the first semiconductor layer through the source/drain trenches to form a first recess; depositing a dielectric material in the first recess to form a bottom dielectric layer; removing the dummy gate structure and the second semiconductor layers to form a gate trench; and forming a gate structure in the gate trench. The gate structure is wrapped around the third semiconductor layers. The bottom dielectric layer is sandwiched between the substrate and the gate structure.

In some embodiments, the method further includes partially recessing the second semiconductor layers exposed in the source/drain trenches to form inner spacer recesses; and forming inner spacers in the inner spacer recesses. A bottommost pair of the inner spacers are separated from the substrate by the bottom dielectric layer.

In some embodiments, the method further includes before the depositing the dielectric material in the first recess, partially recessing the second semiconductor layers exposed in the source/drain trenches to form inner spacer recesses; and depositing the dielectric material in the first recess and the inner spacer recesses to form the bottom dielectric layer and inner spacers, respectively. The bottom dielectric layer is connected to a bottommost pair of the inner spacers.

In some embodiments, the method further includes forming an undoped epitaxial layer in each of the source/drain trenches; and forming a doped epitaxial layer on the undoped epitaxial layer in each of the source/drain trenches. The bottom dielectric layer is in contact with and between the undoped epitaxial layers.

In yet another of the embodiments, discussed is a semiconductor structure. The semiconductor structure includes a substrate; nanostructures suspended over and vertically arranged over the substrate; and a gate structure wrapped around each of the nanostructures. The gate structure includes a gate dielectric layer and a gate electrode layer formed on the gate dielectric layer. The semiconductor structure further includes inner spacers formed on opposite sides of the gate structure, between the nanostructure, and separating the nanostructures from each other, wherein a bottommost pair of the inner spacers extend into the substrate; and a bottom dielectric layer formed below the gate structure and between the bottommost pair of the inner spacers. The bottommost pair of the inner spacers contact opposite sides of the bottom dielectric layer. The bottom dielectric layer is in contact with the gate structure and separates the gate structure from the substrate.

In some embodiments, the semiconductor structure further includes source/drain features attached to opposite sides of the nanostructure. Each of the source/drain features includes an undoped epitaxial layer and a doped epitaxial layer over the undoped epitaxial layer in a Z-direction. The bottom dielectric layer is separated from the undoped epitaxial layers by the bottommost pair of the inner spacers.

In some embodiments, the semiconductor structure further includes gate spacers formed on opposite sides of the gate structure and over a topmost one of the nanostructures; and a gate top dielectric formed over the gate structure and the gate spacers.

In some embodiments, the semiconductor structure further includes source/drain features attached to opposite sides of the nanostructures; and source/drain contacts formed on the source/drain features. The source/drain contacts are separated from the gate structure by the gate spacers. A width of each of the gate spacers is greater than a width of each of the inner spacers.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a substrate;
first nanostructures, suspended over and vertically arranged over the substrate;
a first gate structure, wrapped around each of the first nanostructures;
gate spacers, formed on opposite sides of the first gate structure and over a topmost one of the first nanostructures;
first source/drain features, attached to opposite sides of the first nanostructures; and
a first bottom dielectric layer, formed over the substrate and below the first nanostructures, wherein the first bottom dielectric layer is vertically sandwiched between the substrate and the first gate structure.

2. The semiconductor structure of claim 1, further comprising:
inner spacers, formed on opposite sides of the first gate structure and separating the first nanostructures from each other,
wherein the first bottom dielectric layer is below the inner spacers and sandwiched between a bottommost pair of the inner spacers and the substrate.

3. The semiconductor structure of claim 1, further comprising:
inner spacers, formed on opposite sides of the first gate structure and separating the first nanostructures from each other,
wherein a bottommost pair of the inner spacers extends downward in a vertical direction and contacts opposite sides of the first bottom dielectric layer.

4. The semiconductor structure of claim 1, wherein a thickness of the first bottom dielectric layer is in a range from about 3 nm to about 30 nm.

5. The semiconductor structure of claim 1,
wherein each of the first source/drain features comprises an undoped epitaxial layer and a doped epitaxial layer over the undoped epitaxial layer; and
wherein the first bottom dielectric layer is in contact with and between the undoped epitaxial layers.

6. The semiconductor structure of claim 5, wherein a top surface of the undoped epitaxial layer is higher than a top surface of the first bottom dielectric layer and lower than a bottom surface of a bottommost one of the first nanostructures.

7. The semiconductor structure of claim 1,
wherein the first bottom dielectric layer extends in a horizontal direction; and
wherein the first source/drain features partially cover a top surface of the first bottom dielectric layer.

8. The semiconductor structure of claim 1, further comprising:
second nanostructures, suspended over and vertically arranged over the substrate;
a second gate structure, wrapped around each of the second nanostructures;
second source/drain features, attached to opposite sides of the second nanostructures; and
a second bottom dielectric layer, formed over the substrate and below the second gate structure and the second source/drain features,
wherein the second bottom dielectric layer is sandwiched between the second gate structure and the substrate and sandwiched between the second source/drain features and the substrate, and
wherein the first source/drain features are in direct contact with the substrate.

9. The semiconductor structure of claim 8, wherein the first source/drain features are p-type source/drain features, and the second source/drain features are n-type source/drain features.

10. The semiconductor structure of claim 8, wherein the first nanostructures, the first gate structure, the first source/drain features, and the first bottom dielectric layer are formed on an n-type well region, and the second nanostructures, the second gate structure, the second source/drain features, and the second bottom dielectric layer are formed on a p-type well region.

11. A semiconductor structure, comprising:
a substrate;
first nanostructures, suspended over and vertically arranged over the substrate in a Z-direction;
a first gate structure, extending in a Y-direction and wrapped around each of the first nanostructures;
first source/drain features, attached to opposite sides of the first nanostructures in an X-direction;
first inner spacers, formed on opposite sides of the first gate structure in the X-direction and between the first nanostructure in the Z-direction; and
a first bottom dielectric layer, formed below the first gate structure in the Z-direction and connected to a bottommost pair of the first inner spacers,
wherein the first bottom dielectric layer is in contact with the first gate structure and separates the first gate structure form the substrate in the Z-direction.

12. The semiconductor structure of claim 11,
wherein each of the first source/drain features comprises an undoped epitaxial layer and a doped epitaxial layer over the undoped epitaxial layer in the Z-direction; and
wherein the first bottom dielectric layer is in contact with and between the undoped epitaxial layers in the X-direction.

13. The semiconductor structure of claim 11, further comprising gate spacers formed on opposite sides of the first gate structure in the X-direction and over a topmost one of the first nanostructures in the Z-direction, wherein a width of each of the gate spacers is greater than a width of each of the first inner spacers in the X-direction.

14. The semiconductor structure of claim 11, wherein the first inner spacers and the first bottom dielectric layer are formed of the same material.

15. The semiconductor structure of claim 11, further comprising:
second nanostructures, suspended over and vertically arranged over the substrate in the Z-direction;
a second gate structure, extending in the Y-direction and wrapped around each of the second nanostructures;
second source/drain features, attached to opposite sides of the second nanostructures in the X-direction;
second inner spacers, formed on opposite sides of the second gate structure in the X-direction and between the second nanostructures in the Z-direction; and
a second bottom dielectric layer, formed below the second gate structure and the second source/drain features in the Z-direction, and connected to a bottommost pair of the second inner spacers,
wherein the second bottom dielectric layer separated the second source/drain features from the substrate in the Z-direction, and
wherein the first source/drain features are in direct contact with opposite sides of the first bottom dielectric layer in the X-direction.

16. The semiconductor structure of claim 15, wherein the first source/drain features are p-type source/drain features, and the second source/drain features are n-type source/drain features.

17. A method of forming a semiconductor structure, comprising:
forming a fin structure over a substrate, wherein the fin structure comprises a first semiconductor layer over the substrate, and second semiconductor layers and third semiconductor layers alternately stacked over the first semiconductor layer;
forming a dummy gate structure over the fin structure;
forming source/drain trenches in the fin structure on opposite sides of the dummy gate structure;
removing the first semiconductor layer through the source/drain trenches to form a first recess;
depositing a dielectric material in the first recess to form a bottom dielectric layer;
removing the dummy gate structure and the second semiconductor layers to form a gate trench; and
forming a gate structure in the gate trench, wherein the gate structure is wrapped around the third semiconductor layers,
wherein the bottom dielectric layer is sandwiched between the substrate and the gate structure.

18. The method of claim 17, further comprising:
partially recessing the second semiconductor layers exposed in the source/drain trenches to form inner spacer recesses; and
forming inner spacers in the inner spacer recesses, wherein a bottommost pair of the inner spacers are separated from the substrate by the bottom dielectric layer.

19. The method of claim 17, further comprising:
before the depositing the dielectric material in the first recess, partially recessing the second semiconductor layers exposed in the source/drain trenches to form inner spacer recesses; and
depositing the dielectric material in the first recess and the inner spacer recesses to form the bottom dielectric layer and inner spacers, respectively, wherein the bottom dielectric layer is connected to a bottommost pair of the inner spacers.

20. The method of claim 17, further comprising:
forming an undoped epitaxial layer in each of the source/drain trenches; and
forming a doped epitaxial layer on the undoped epitaxial layer in each of the source/drain trenches,
wherein the bottom dielectric layer is in contact with and between the undoped epitaxial layers.
